(19) United States
(12) Patent Application Publication
(10) Pub. No.: US 2008/0197449 A1
(43) Pub. Date: Aug. 21, 2008

(54) WIRING STRUCTURE OF SEMICONDUCTOR INTEGRATED CIRCUIT DEVICE, AND METHOD AND DEVICE FOR DESIGNING THE SAME

(76) Inventors: Takayuki ARAKI, Nara (JP); Junichi Shimada, Shiga (JP); Hirokazu Ogawa, Osaka (JP); Kazuhiko Fujimoto, Osaka (JP); Tsutomu Fujii, Osaka (JP); Takuya Yasui, Osaka (JP)

Correspondence Address: MCDERMOTT WILL & EMERY LLP, 600 13TH STREET, NW, WASHINGTON, DC, 20005-3096, US

(21) Appl. No.: 12/035,230

(22) Filed: Feb. 21, 2008

(30) Foreign Application Priority Data
Feb. 21, 2007 (JP) 2007-040981

(51) Int. Cl. H01L 23/52

(52) U.S. Cl. 257/522; 257/E23.141

(57) ABSTRACT

A method is provided for designing a wiring structure of a wiring layer of a semiconductor integrated circuit device. The method includes a wire width detecting step of detecting a wire width of each wire in a wiring pattern of layout data, a wire identifying step of identifying a wire having a predetermined wire width or more based on a result of detection by the wire width detecting step, a wiring pitch detecting step of detecting a wiring pitch between the wire identified by the wire identifying step and another wire, and an air gap-forbidden region forming and removing step of forming or removing an air gap-forbidden region, depending on a result of detection by the wiring pitch detecting step.

### CROSS REFERENCE TO RELATED APPLICATIONS

This Non-provisional application claims priority under 35 U.S.C. §119(a) on Patent Application No. 2007-040981 filed in Japan on Feb. 21, 2007, the entire contents of which are hereby incorporated by reference.

### BACKGROUND OF THE INVENTION

1. Field of the Invention

The present invention relates to a wiring structure of a semiconductor integrated circuit device having an air gap in a miniaturization process, and a method and device for designing the wiring structure.

2. Description of the Related Art

In recent years, the integration density of a semiconductor integrated circuit is significantly increasing with advances in semiconductor miniaturization processes. However, as the integration density is increased, a wiring pitch is extremely narrowed, resulting in an increase in parasitic capacitance. The increase in inter-wire parasitic capacitance leads to a crosstalk phenomenon that an electrical signal leaks between wires, an increase in RC delay of a wire, and an increase in power consumption.

Therefore, in the field of semiconductor manufacturing technology, an inter-layer insulating film having a low dielectric constant (low-k film) which reduces an inter-wire parasitic capacitance has been actively studied for 45-nm or below processes. Also, a wiring structure has been proposed in which a space formed by air (hereinafter referred to as an air gap) is deliberately provided between wires, rather than the low-k film (see, for example, Japanese Patent No. 2087547). It is considered that the air gap employing air, which has a dielectric constant of 1, can obtain an even lower relative dielectric constant than that of the low-k film.

The air gap is a space which is formed when an insulating film deposited on a metal layer does not flow down. When the air gap is formed, there is an upper limit value of an opening width of an air gap-formed region, depending on a material for the insulating film. Therefore, a technique of reducing a wiring pitch by adding a dummy pattern so as to increase the number of air gaps has been proposed as a method for designing a wiring structure of a semiconductor integrated circuit (see, for example, Japanese Patent No. 3481222).

Another manufacturing method for forming the air gap includes etching an air gap forming portion using a resist pattern masking an air gap-forbidden region after inserting a metal layer into an insulating film. In this case, it has been proposed that an air gap-forbidden region is provided around a via so as to prevent penetration between the air gap and the via due to misalignment occurring during manufacture of a semiconductor integrated circuit (see, for example, Japanese Unexamined Patent Application Publication No. 2006-120988).

### SUMMARY OF THE INVENTION

However, conventional air gap formation has the following problems.

Firstly, wire width, wiring density, and wiring evenness are not taken into consideration of the formation of an air gap-forbidden region. A portion having a large wire width or a portion having a high wiring density and a vicinity thereof are considerably easily worn out when an insulating film is polished, so that an upper portion of the air gap is likely to be cut out. Resistance to polishing may also vary depending on wiring evenness as well as wiring density. In the technique of Japanese Patent No. 3481222 above, in order to prevent the opening width of the air gap-formed region from exceeding the upper limit value of air gap formation, the wiring pitch is reduced by adding a dummy pattern so as to increase the number of air gaps. However, as is similar to that which has been described above, the wire width and the like in the semiconductor integrated circuit are not taken into consideration.

Also, disadvantageously, it is not taken into consideration that the air gap has a risk of penetrating an insulating film thereabove, depending on the size of the air gap. The air gap has an upper portion which is in the shape of a circular cone due to deposition of the insulating film. If a wiring pitch which forms the air gap is large, so that the circular cone portion has a great height, it is likely that a top portion of the air gap is cut out when the insulating film is polished. The upper film flows into this space, resulting in a decrease in yield.

Secondly, the possibility that a wire above an air gap may be slid down by formation of the air gap is not taken into consideration of the design of a semiconductor integrated circuit. The air gap is a space which is formed when an insulating film deposited on a metal layer does not flow down. In the technique of Japanese Unexamined Patent Application Publication No. 2006-120988, an air gap-forbidden region is provided around a via so as to prevent penetration between an air gap and the via due to misalignment occurring during manufacture of a semiconductor integrated circuit. However, wiring is not taken into consideration. Also, an increase in mask cost due to the formation of the air gap-forbidden region is not taken into consideration.

Thirdly, in the technique of Japanese Unexamined Patent Application Publication No. 2006-120988, an air gap-forbidden region is provided around a via so as to prevent penetration between an air gap and the via due to misalignment occurring during manufacture of a semiconductor integrated circuit. However, the possibility that the air gap-forbidden region around the via makes it difficult to perform wiring, is not taken into consideration. The deterioration in wiring performance may lead to an increase in chip area. Also, as is similar to that which has been described above, an increase in mask cost due to the formation of the air gap-forbidden region is not taken into consideration.

In view of the above-described problems, the present invention has been achieved. An object of the present invention is to provide a wiring structure of a semiconductor integrated circuit device in which a minimum number of air gaps are formed, taking into consideration the advantages and disadvantages of a reduction in inter-wire parasitic capacitance due to the air gap, and the yield, or in which an air gap-forbidden region is easily formed, and a method and device for designing the same.

To achieve the object, the present invention provides a structure in which the formation of an air gap or an air gap-forbidden region can be controlled in a short period of time with respect to a wiring pattern which leads to a decrease in yield when an air gap is formed in the vicinity thereof.

Specifically, a wiring structure designing method according to a first aspect of the present invention is a method for designing a wiring structure of a wiring layer of a semiconductor integrated circuit device, comprising a wire width detecting step of detecting a wire width of each wire in a wiring pattern of layout data, a wire identifying step of identifying a wire having a predetermined wire width or more based on a result of detection by the wire width detecting step, a wiring pitch detecting step of detecting a wiring pitch between the wire identified by the wire identifying step and another wire, and an air gap-forbidden region forming and removing step of forming or removing an air gap-forbidden region, depending on a result of detection by the wiring pitch detecting step.

A wiring structure designing method according to a second aspect of the present invention is a method for designing a wiring structure of a wiring layer of a semiconductor integrated circuit device, comprising a wiring density detecting step of detecting a wiring density of each wiring region in a wiring pattern of layout data, a region identifying step of identifying a wiring region having a predetermined wiring density or more based on a result of detection by the wiring density detecting step, and an air gap-forbidden region forming and removing step of forming or removing an air gap-forbidden region with respect to the wiring region identified by the region identifying step and a region therearound.

A wiring structure according to a third aspect of the present invention is a wiring structure of a wiring layer having an air gap of a semiconductor integrated circuit device, in which an air gap is provided only in a wiring region or wiring regions in which a wiring pitch between a large-width wire and another wire has a predetermined value or less.

A wiring structure according to a fourth aspect of the present invention is a wiring structure of a wiring layer having an air gap of a semiconductor integrated circuit device, in which an air gap is provided only in a wiring region or wiring regions in which a wiring density has a predetermined value or less.

A wiring structure designing device according to a fifth aspect of the present invention is a device for designing a wiring structure of a wiring layer of a semiconductor integrated circuit device, comprising an evenness detecting section for detecting an evenness of each wire in a wiring pattern of layout data, a wire identifying section for identifying a wire in which a step having a predetermined value or more appears, based on a result of detection by the evenness detecting section, and an air gap-forbidden region forming and removing section for forming or removing an air gap-forbidden region with respect to a region around the wire identified by, the wire identifying section.

A wire structure designing method according to a sixth aspect of the present invention is a method for designing a wiring structure of a wiring layer of a semiconductor integrated circuit device, comprising a wiring pitch detecting step of detecting a space between wires in which an air gap can be formed, based on a wiring pattern of layout data, an area detecting step of detecting whether or not a region of the space between wires detected by the wiring pitch detecting step has a predetermined area or more, and an air gap forming step of forming an air gap and an air gap-forbidden region in the region when it is determined in the area detecting step that the region has the predetermined area or more.

A wiring structure according to a seventh aspect of the present invention is a wiring structure of a wiring layer having an air gap of a semiconductor integrated circuit device, in which an air gap and an insulating film are provided between wires in the wiring layer.

A wiring structure according to an eighth aspect of the present invention is a wiring structure of a semiconductor integrated circuit device having a multilayer wiring structure having an air gap, in which an air gap is provided only either in an odd-number layer or layers or an even-number layer or layers in a multilayer wiring layer.

A wiring structure according to a ninth aspect of the present invention is a wiring structure of a semiconductor integrated circuit device having a multilayer wiring structure having an air gap, in which an air gap is provided only in an odd-number layer or layers in a region of a portion of a multilayer wiring layer, and an air gap is provided only in an even-number layer or layers in the other region of the multilayer wiring layer.

A device for designing a wiring structure according to a tenth aspect of the present invention is a device for designing a wiring structure of a semiconductor integrated circuit device having a multilayer wiring structure, comprising an air gap-formed region extracting section for extracting an air gap-formed region of each wiring layer based on a wiring pattern of layout data, an air gap overlapping portion detecting section for detecting, with reference to a wiring layer, an overlapping portion between an air gap-formed region of the reference layer, and an air gap-formed region of a wiring layer immediately above or below the reference layer, based on a result of detection by the air gap-formed region extracting section, and an air gap-forbidden region forming section for forming an air gap-forbidden region in the air gap-formed region of at least one of the reference layer and the wiring layer immediately above or below the reference layer, with respect to the overlapping portion detected by the air gap overlapping portion detecting section.

A wiring structure according to an eleventh aspect of the present invention is a wiring structure of a semiconductor integrated circuit device having a multilayer wiring structure having an air gap, in which an air gap-forbidden region formed in a layer above the air gap has the same length as that of the air gap, and the same width as that of a closest air gap in the same wiring layer as that of the air gap-forbidden region.

A wiring structure according to a twelfth aspect of the present invention is a wiring structure of a semiconductor integrated circuit device having a multilayer wiring structure having an air gap, in which an air gap-forbidden region formed in a layer below the air gap has the same length as that of the air gap, and the same width as that of a closest air gap in the same wiring layer as that of the air gap-forbidden region.

A method for designing a wiring structure according to a thirteenth aspect of the present invention is a method for designing a wiring structure of a semiconductor integrated circuit device having a multilayer wiring structure, comprising a wiring pitch detecting step of detecting a space between wires in which an air gap can be formed, based on a wiring pattern of layout data, an upper-layer wire detecting step of detecting whether or not an upper-layer wire is present in a layer above a region of the space between wires detected by the wiring pitch detecting step, and an upper-layer wire connecting step of connecting the upper-layer wire to a wire on an insulating film in the same wiring layer as that of the upper-layer wire when it is detected in the upper-layer wire detecting step that the upper-layer wire is present in the layer above the region.

A wiring structure according to a fourteenth aspect of the present invention is a wiring structure of a semiconductor integrated circuit device having a multilayer wiring structure having an air gap, in which an upper-layer wire present in a layer above the air gap is connected to a wire on an insulating film in the same wiring layer as that of the upper-layer wire at at least one point.

A method for designing a wiring structure according to a fifteenth aspect of the present invention is a method for designing a wiring structure of a semiconductor integrated circuit device having a multilayer wiring structure, comprising a wiring pitch detecting step of detecting a space between wires in which an air gap can be formed, based on a wiring pattern of layout data, an upper-layer wire detecting step of detecting whether or not an upper-layer wire is present in a layer above a region of the space between wires detected by the wiring pitch detecting step, and an overlap avoiding step of, when it is detected in the upper-layer wire detecting step that an upper-layer wire is present in the layer above the region and an entirety of at least one side of the upper-layer wire overlaps an end portion of an air gap-formed region, preventing the side of the upper-layer wire from overlapping the end portion of the air gap-formed region.

A wiring structure according to a sixteenth aspect of the present invention is a wiring structure of a semiconductor integrated circuit having a multilayer wiring structure having an air gap, in which an entirety of at least one side of an upper-layer wire present in a layer above the air gap does not overlap an end portion of the underlying air gap.

A method for designing a wiring structure according to a seventeenth aspect of the present invention is a method for designing a wiring structure of a semiconductor integrated circuit device having a multilayer wiring structure, comprising a wiring pitch detecting step of detecting a space between wires in which an air gap can be formed, based on a wiring pattern of layout data, an upper-layer wire detecting step of detecting whether or not an upper-layer wire is present in a layer above a region of the space between wires detected by the wiring pitch detecting step, an overlap area detecting step of detecting an overlap area between the region and the upper-layer wire, and an air gap-forbidden region forming step of forming an air gap-forbidden region at a portion of the region when the overlap area is a predetermined area or more.

A wiring structure according to an eighteenth aspect of the present invention is a wiring structure of a semiconductor integrated circuit having a multilayer wiring structure having an air gap, in which at least one insulator is provided in an air gap-formed region of a reference layer and at an overlapping portion between the air gap-formed region of the reference layer and an upper-layer wire present in a layer above the reference layer.

A wiring structure according to a nineteenth aspect of the present invention is a wiring structure of a wiring layer having an air gap of a semiconductor integrated circuit device, in which a wire connected to a via adjacent to the air gap has a larger protrusion amount in a direction in which the air gap is present than in the other directions.

A method for designing a wiring structure according to a twentieth aspect of the present invention is a method for designing a wiring structure of a wiring layer of a semiconductor integrated circuit device, comprising an air gap-formed region extracting step of extracting an air gap-formed region based on a wiring pattern of layout data, an adjacent via identifying step of identifying a via adjacent to the air gap-formed region extracted by the air gap-formed region extracting step, a wire side detecting step of detecting a wire connected to the via identified by the adjacent via identifying step and detecting a side contacting the air gap-formed region of the wire, and a wire protrusion amount increasing step of enlarging the wire side detected by the wire side detecting step to increase a protrusion amount of the wire connected to the via.

A twenty-first aspect of the present invention is the method of the twenties aspect further comprising a surrounding wire moving step of moving a wire around the wire detected by the wire side detecting step when the wire side detected by the wire side detecting step is enlarged.

A method for designing a wiring structure according to a twenty-second aspect of the present invention is a method for designing a wiring structure of a wiring layer of a semiconductor integrated circuit device, comprising an air gap-formed region extracting step of extracting an air gap-formed region based on a wiring pattern of layout data, an adjacent via identifying step of identifying a via adjacent to the air gap-formed region extracted by the air gap-formed region extracting step, and a via position changing step of changing a position of the via identified by the adjacent via identifying step.

A method for designing a wiring structure according to a twenty-third aspect of the present invention is a method for designing a wiring structure of a wiring layer of a semiconductor integrated circuit device, comprising a wire name setting step of setting a wire name for a wire forming a wiring pattern without a via, based on layout data, a wire forming region designating step of designating a region in which the wire set by the wire name setting step will be formed, an air gap forming pitch designating step of designating pitch information about a space between wires in which an air gap will be formed, based on the layout data, and a wiring pattern forming step of forming a wiring pattern of the wire set by the wire name setting step at a wiring pitch smaller than or equal to that designated by the air gap forming pitch designating step, in the region designated by the wire forming region designating step.

Thus, in the first to seventh aspects, an air gap-forbidden region is formed at a portion having a large wire width, a portion having a high wiring density, a portion which is easily worn out by polishing due to the unevenness of wires, or a surrounding region thereof in a semiconductor integrated circuit device, thereby suppressing formation of an air gap having a high circular cone portion, so that a decrease in yield due to defective formation of an air gap. Also, not the entirety of a portion having a large wiring pitch is caused to be air gap-forbidden region, i.e., an air gap and an air gap-forbidden region are formed in the portion, thereby making it possible to efficiently form the air gap.

In the eighth to eighteenth aspects, in view of the possibility that air gap formation leads to sliding down of an upper-layer wire in a layer above an air gap, the upper-layer wire is connected to another wire in the same layer, or an overlap between an end portion of the air gap and an end portion of the upper-layer wire is avoided. Thereby, it is possible to suppress a decrease in yield due to sliding down of the upper-layer wire into the air gap. Also, an air gap-forbidden region is not provided when the upper-layer wire is prevented from sliding down, so that it is possible to suppress an increase in mask cost due to formation of an air gap-forbidden region.

In the nineteenth to twenty-third aspects, a protrusion amount of a wire connected to a via adjacent to an air gap is increased, or a position of the via is changed, thereby making it possible to suppress a decrease in yield due to missing of a via with respect to an air gap. Also, an air gap-forbidden region is not provided around a via, thereby making it possible to reduce a deterioration in wiring performance, and therefore, suppress an increase in chip area, and in addition, suppress an increase in mask cost due to formation of an air gap-forbidden region.

### BRIEF DESCRIPTION OF THE DRAWINGS

FIG. 1 is a diagram schematically showing a configuration of a wiring structure designing device according to a first embodiment of the present invention.

FIG. 2A is a plan view of a typical wiring pattern in one wiring layer of a multilayer wiring structure.

FIG. 2B is a cross-sectional view taken along line A-A′ of FIG. 2A.

FIG. 2C is a cross-sectional view taken along line A-A′ of FIG. 2A after CMP with respect to the wiring pattern of FIG. 2A.

FIG. 2D is a cross-sectional view of the wiring pattern of FIG. 2C in which an insulating film is deposited to form air gaps.

FIG. 3A is a plan view of a typical wiring pattern in one wiring layer of a multilayer wiring structure.

FIG. 3B is a cross-sectional view taken along line A-A′ of FIG. 3A.

FIG. 3C is a cross-sectional view taken along line A-A′ of the wiring pattern of FIG. 3A in which air gap-forbidden regions are formed.

FIG. 3D is a cross-sectional view of the wiring pattern of FIG. 3C in which an insulating film is deposited.

FIG. 4A is a plan view of a typical wiring pattern in one wiring layer of a multilayer wiring structure.

FIG. 4B is a cross-sectional view taken along line A-A′ of FIG. 4A.

FIG. 4C is a cross-sectional view taken along line B-B′ of FIG. 4A after CMP with respect to the wiring pattern of FIG. 4A.

FIG. 4D is a cross-sectional view of the wiring pattern of FIG. 4C in which an insulating film is deposited to form air gaps.

FIG. 5 is a diagram schematically showing another wiring structure designing device according to the first embodiment.

FIG. 6A is a plan view of a typical wiring pattern in one wiring layer of a multilayer wiring structure.

FIG. 6B is a cross-sectional view taken along line B-B′ of FIG. 6A.

FIG. 6C is a cross-sectional view taken along line B-B′ of the wiring pattern of FIG. 6A in which air gap-forbidden regions are formed.

FIG. 6D is a cross-sectional view of the wiring pattern of FIG. 6C in which an insulating film is deposited.

FIG. 7 is a flowchart showing a process flow of a method for designing the wiring structure of the first embodiment and another wiring structure.

FIG. 8 is a diagram schematically showing a configuration of a wiring structure designing device according to a second embodiment of the present invention.

FIG. 9A is a plan view of a typical wiring pattern in one wiring layer of a multilayer wiring structure.

FIG. 9B is a cross-sectional view taken along line B-B′ of FIG. 9A.

FIG. 9C is a cross-sectional view taken along line B-B′ of the wiring pattern of FIG. 9A in which air gap-forbidden regions are formed.

FIG. 9D is a cross-sectional view of the wiring pattern of FIG. 9C in which an insulating film is deposited.

FIG. 10 is a flowchart showing a process flow of a wiring structure designing method according to a third embodiment of the present invention.

FIG. 11A is a layout diagram before the wiring structure designing method of the third embodiment is performed.

FIG. 11B is a layout diagram after the wiring structure designing method of the third embodiment is performed.

FIG. 12 is a plan view of the wiring structure of a semiconductor integrated circuit device according to a fourth embodiment of the present invention.

FIG. 13 is a plan view of a conventional multilayer wiring structure of a semiconductor integrated circuit device having an air gap.

FIG. 14 is a plan view of a multilayer wiring structure of a semiconductor integrated circuit device having an air gap according to the present invention.

FIG. 15 is a plan view of another multilayer wiring structure of a semiconductor integrated circuit device having an air gap according to the present invention.

FIG. 16 is a plan view of a wiring structure of a semiconductor integrated circuit device according to a fifth embodiment of the present invention.

FIGS. 17A and 17B are diagrams showing a process of the wiring structure designing method of the fifth embodiment.

FIGS. 18A and 18B are diagrams showing a process of steps following FIGS. 17A and 17B of the wiring structure designing method of the fifth embodiment.

FIG. 19 is a plan view of a wiring structure of a semiconductor integrated circuit device having an air gap according to the fifth embodiment.

FIG. 20 is a flowchart showing a process flow of a wiring structure designing method according to a sixth embodiment of the present invention.

FIG. 21A is a layout diagram before the wiring structure designing method of the sixth embodiment is performed.

FIG. 21B is a layout diagram after the wiring structure designing method of the sixth embodiment is performed.

FIG. 22 is a flowchart showing a process flow of a wiring structure designing method according to a seventh embodiment of the present invention.

FIG. 23A is a layout diagram before the wiring structure designing method of the seventh embodiment is performed.

FIG. 23B is a layout diagram after the wiring structure designing method of the seventh embodiment is performed.

FIG. 24 is a flowchart showing a process flow of a wiring structure designing method according to an eighth embodiment of the present invention.

FIG. 25A is a layout diagram before the wiring structure designing method of the eighth embodiment is performed.

FIG. 25B is a layout diagram after the wiring structure designing method of the eighth embodiment is performed.

FIG. 26 is a plan view of a wiring structure of a semiconductor integrated circuit device according to a ninth embodiment of the present invention.

FIG. 27 is a flowchart showing a process flow of the wiring structure designing method of the ninth embodiment.

FIG. 28 is a plan view of a wiring structure of a semiconductor integrated circuit device designed using the wiring structure designing method of the ninth embodiment.

FIG. 29 is a plan view of another wiring structure of a semiconductor integrated circuit device designed using the wiring structure designing method of the ninth embodiment.

FIG. 30 is a plan view of the wiring structure of a semiconductor integrated circuit device according to a tenth embodiment of the present invention.

FIG. 31 is a plan view of another wiring structure of a semiconductor integrated circuit device of the tenth embodiment.

FIG. 32 is a flowchart showing a process flow of the wiring structure designing method of the tenth embodiment.

FIG. 33 is a flowchart showing a process flow of a wiring structure designing method according to an eleventh embodiment of the present invention.

FIG. 34 is a plan view of a wiring structure of a semiconductor integrated circuit device designed using the wiring structure designing method of the eleventh embodiment.

### DETAILED DESCRIPTION OF THE PREFERRED EMBODIMENTS

Hereinafter, a wiring structure of a semiconductor integrated circuit device according to the present invention, and a method and device for designing the wiring structure will be described, by way of embodiments, with reference to the accompanying drawings.

### First Embodiment

Hereinafter, a method and device for designing a wiring structure according to a first embodiment of the present invention, and a wiring structure obtained by the designing method and device, will be described.

In this embodiment, by identifying a step appearing portion and forming an air gap-forbidden region with respect to the step appearing portion, a top portion of an air gap is prevented from being removed by CMP.

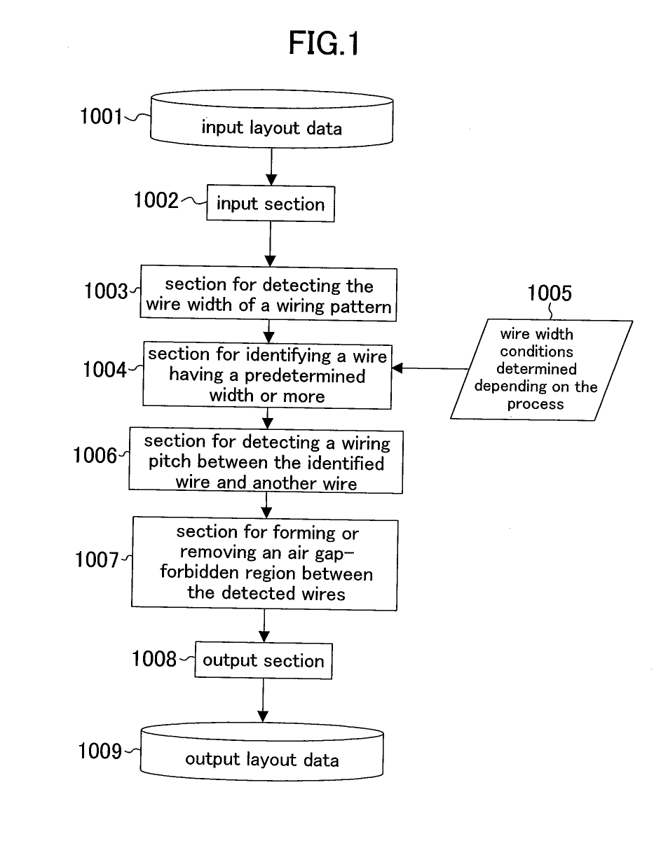

FIG. 1 is a diagram schematically showing a configuration of the wiring structure designing device of the first embodiment of the present invention.

In FIG. 1, the wiring structure designing device of the semiconductor integrated circuit device comprises an input section 1002 for inputting data 1001 of a layout after wiring, a section 1003 for detecting a wire width of each wire in a wiring pattern of the input layout data 1001, a section 1004 for identifying a wire having a predetermined width or more based on the result of detection by the section 1003 using wire width conditions 1005 which are determined, depending on the process, a section 1006 for detecting a wiring pitch between the wire identified by the section 1004 and another wire, a section 1007 for forming or removing an air gap-forbidden region, depending on the result of detection by the section 1006, and a section 1008 for outputting data 1009 of a layout including the air gap-forbidden region determined by the section 1007.

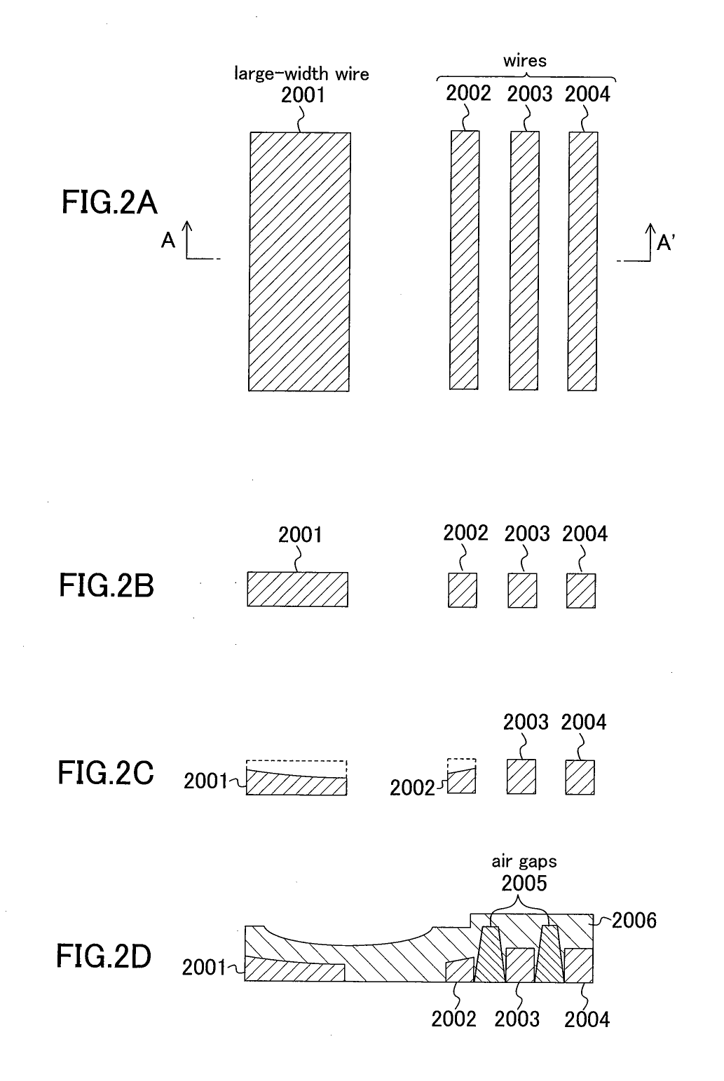

Hereinafter, the wiring structure of the semiconductor integrated circuit device of this embodiment will be described with reference to FIGS. 2A to 2D.

FIG. 2A is a plan view of a typical wiring pattern in one wiring layer of a multilayer wiring structure. A wire 2001 is a wire having a large width which is mainly used for a power source or the like, and wires 2002, 2003, and 2004 are wires having a minimum width which are mainly used for signal wires or the like. FIG. 2B is a cross-sectional view taken along line A-A′ of FIG. 2A. FIG. 2C is a cross-sectional view taken along line A-A′ of FIG. 2A after CMP with respect to the wiring pattern of FIG. 2A. FIG. 2D is a cross-sectional view of the wiring pattern of FIG. 2C in which an insulating film 2006 is deposited to form air gaps 2005.

In general, the large-width wire 2001 is easily worn out during CMP. Therefore, in the wiring pattern after CMP, a large portion of the large-width wire 2001 is removed, so that a step appears as shown in FIG. 2C. In this case, when there is a large wiring pitch between the wires 2002 and 2003 in the vicinity of the large-width wire 2001, the air gaps 2005 having a high circular cone portion is formed in the vicinity of the step as shown in FIG. 2D. In this situation, if CMP is performed with respect to the insulating film 2006 to eliminate the step, a top portion of the air gap 2005 having a high circular cone portion is cut out, so that the film above the air gap 2005 flows into the space, leading to a decrease in yield.

In this embodiment, initially, the large-width wire 2001 having the predetermined width or more which is easily worn out by polishing is identified using the section 1004 of FIG. 1. Thereafter, the section 1006 is used to identify a wiring pitch portion which is located in the vicinity of the large-width wire 2001 and in which the air gap 2005 having a high circular cone portion would be formed, and the section 1007 is used to form air gap-forbidden region with respect to the portion.

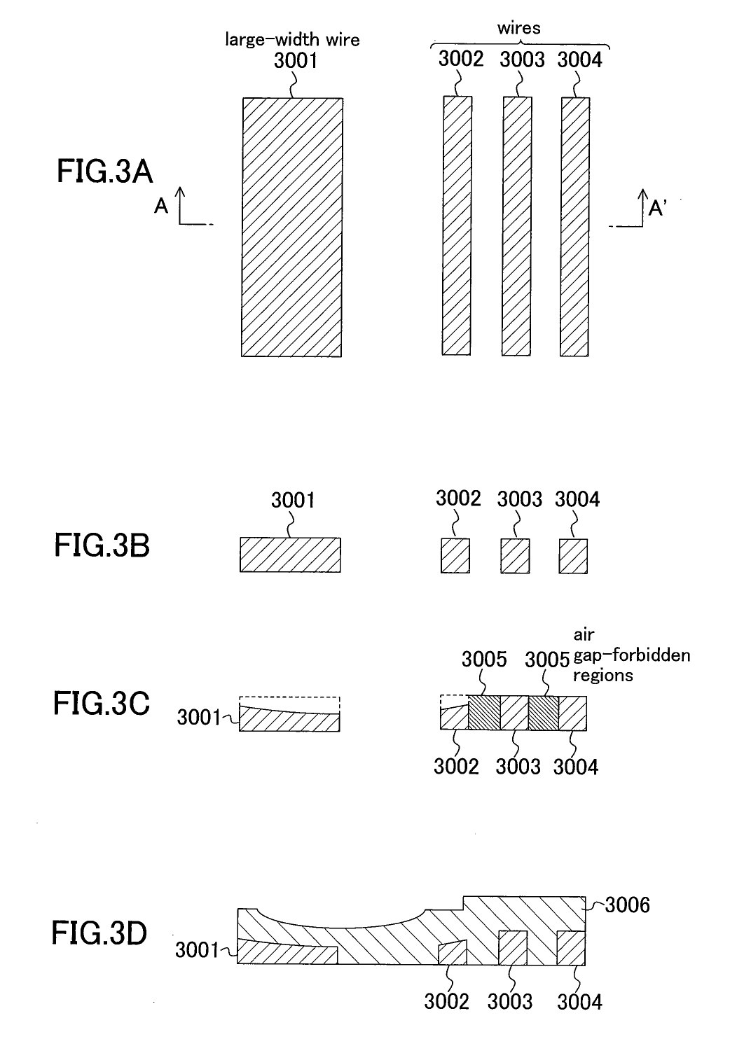

FIGS. 3A to 3D are diagrams showing a wiring structure of one wiring layer of a semiconductor integrated circuit device which is designed using the wiring structure designing device of this embodiment.

FIGS. 3A and 3B are similar to FIGS. 2A and 2B and will not be described. FIG. 3C is a cross-sectional view taken along line A-A′ of the wiring pattern of FIG. 3A in which air gap-forbidden regions 3005 are formed. FIG. 3D is a cross-sectional view of the wiring pattern of FIG. 3C in which an insulating film is deposited.

By using the wiring structure designing device of this embodiment, a wiring pattern as shown in FIG. 3C is obtained in which the air gap-forbidden regions 3005 are formed around a step appearing portion, and an air gap will not be formed in the regions 3005. Therefore, even when CMP is performed, a top portion of an air gap is not cut out, thereby making it possible to suppress a decrease in yield.

Also, in this embodiment, an air gap-forbidden region is formed with respect to only a wiring pitch portion(s) in which an air gap having a high circular cone portion would be otherwise formed, so that a high yield can be secured while leaving a region in which an air gap can be formed.

Hereinafter, another wiring structure designing device according to this embodiment and a wiring structure obtained using the designing device will be described.

In addition to large-width wires, a region having a high wiring density is considered to be a shape which is easily worn out during CMP.

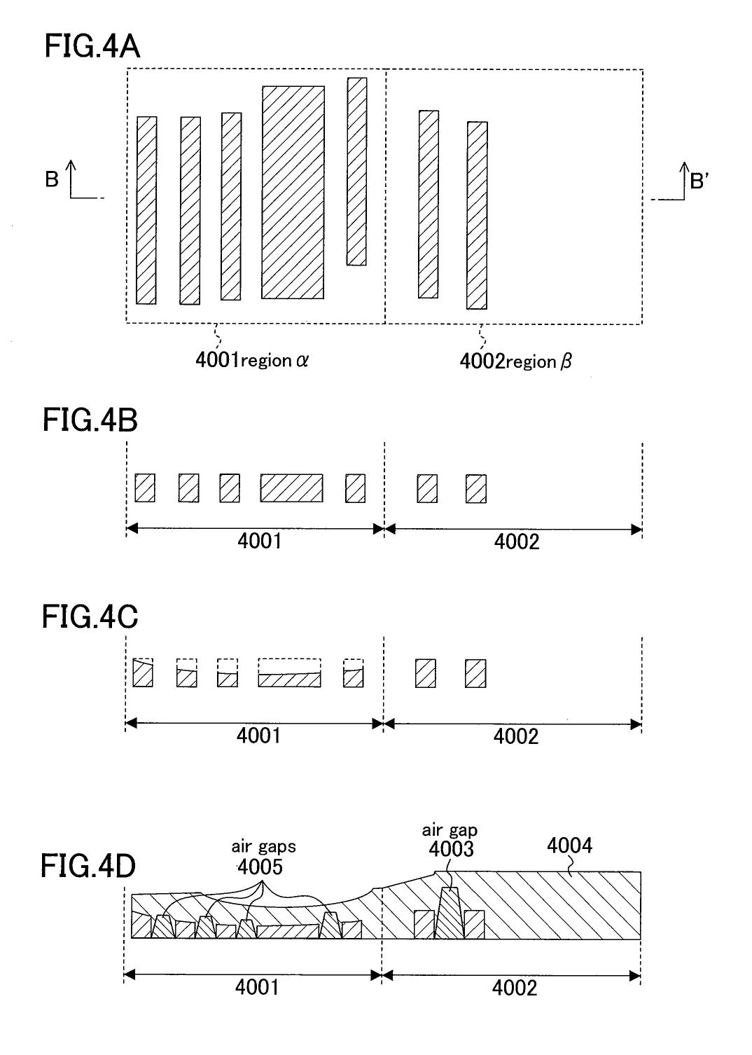

FIG. 4A is a plan view of a typical wiring pattern in one wiring layer of a multilayer wiring structure. FIG. 4B is a cross-sectional view taken along line B-B′ of FIG. 4A. FIG. 4C is a cross-sectional view along line B-B′ of the wiring pattern of FIG. 4A after CMP. FIG. 4D is a cross-sectional view of the wiring pattern of FIG. 4C in which an insulating film 4004 is deposited to form air gaps 4003 and 4005.

It is here assumed that a region,s 4001 has a wiring density of 70%, and a region β 4002 has a wiring density of 20%. In a damascene process, the region α 4001 is easily worn out and the region β 4002 is not easily worn out during CMP. In this case, a step appears between the region α 4001 and the region β 4002 as shown in FIG. 4C. If the air gap 4003 having a high circular cone portion is formed in the vicinity of the step as shown in FIG. 4D, then when CMP is performed with respect to the insulating film 4004, a top portion of the air gap 4003 having the high circular cone portion is cut out. In this case, the layer above the air gap 4003 flows into the space, leading to a decrease in yield.

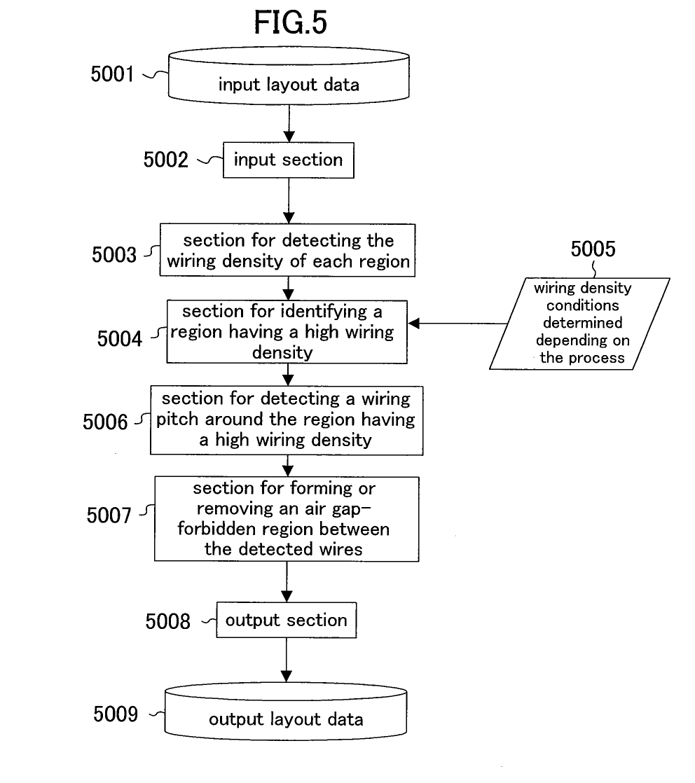

FIG. 5 is a diagram schematically showing another wiring structure designing device according to this embodiment.

In FIG. 5, the device for designing a wiring structure of a semiconductor integrated circuit device comprises an input section 5002 for inputting data 5001 of a layout after wiring, a section 5003 for detecting the wiring density of each wiring region in a wiring pattern of the input layout data 5001, a section 5004 for identifying a wiring region having a predetermined density or more based on the result of detection by the section 5003 using wiring density conditions 5005 determined, depending on the process, a section 5006 for detecting a wiring pitch portion which is located in a region around the wiring region identified by the section 5004 and in which an air gap having a high circular cone portion would be formed, a section 5007 for forming or removing an air gap-forbidden region, depending on the result of detection by the section 5006, and an output section 5008 for outputting data 5009 of a layout including the air gap-forbidden region determined by the section 5007.

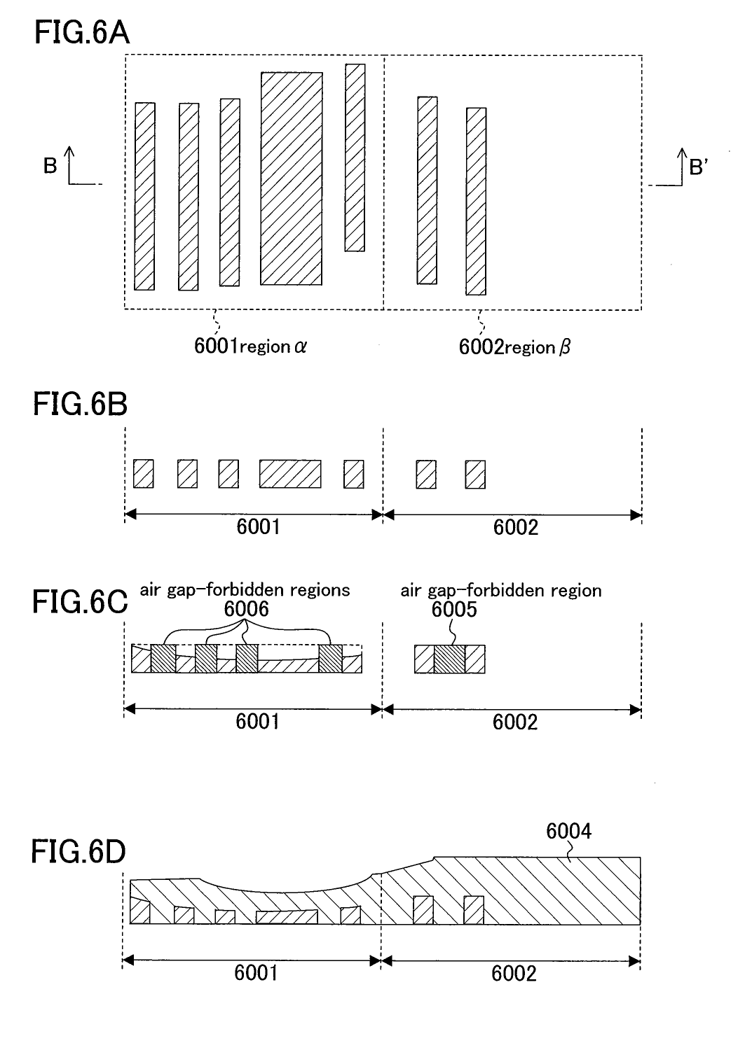

FIGS. 6A to 6D are diagrams showing a wiring structure of one wiring layer of a semiconductor integrated circuit device which is designed using the wiring structure designing device of FIG. 5.

FIGS. 6A and 6B are similar to FIGS. 4A and 4B and will not be described. FIG. 6C is a cross-sectional view taken along line B-B′ of the wiring pattern of FIG. 6A in which air gap-forbidden regions 6005 and 6006 are formed. FIG. 6D is a cross-sectional view of the wiring pattern of FIG. 6C in which an insulating film 6004 is deposited.

By using the wiring structure designing device of this embodiment, a wiring structure as shown in FIG. 6C is obtained in which the air gap-forbidden region 6005 is formed around a step appearing portion so that an air gap will not be formed in the region 6005. Therefore, even when CMP is performed, a top portion of an air gap is not cut out, thereby making it possible to suppress a decrease in yield.

Also, in this embodiment, an air gap-forbidden region is formed with respect to only a wiring pitch portion(s) in which an air gap having a high circular cone portion would be otherwise formed, so that a high yield can be secured while leaving a region in which an air gap can be formed.

Hereinafter, a method for designing the wiring structure of a semiconductor integrated circuit device of this embodiment will be described.

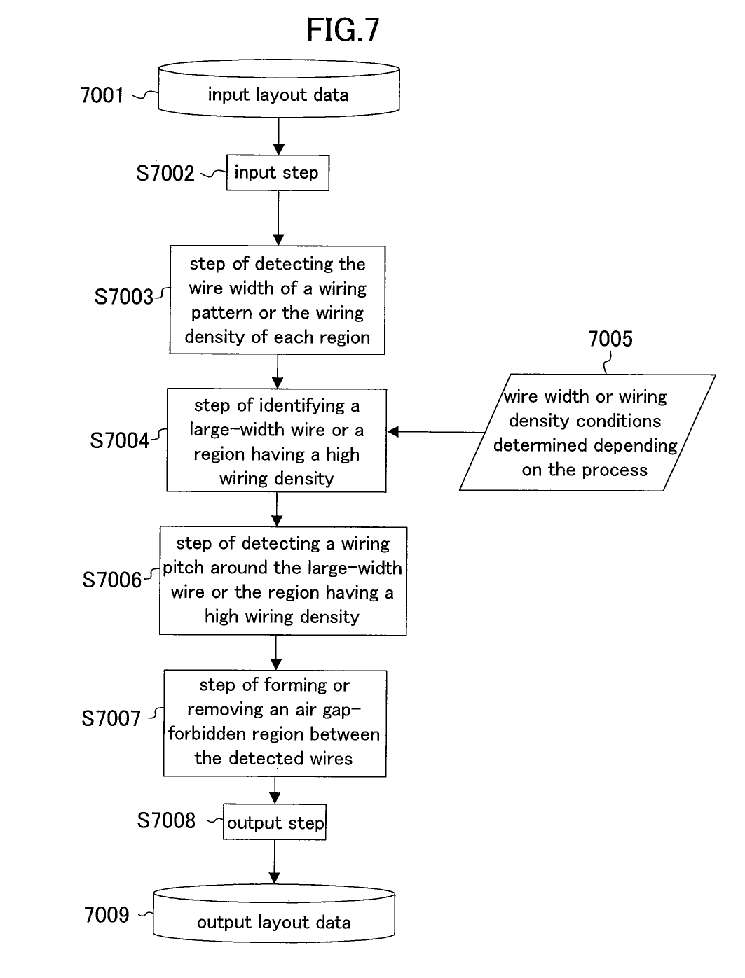

FIG. 7 is a flowchart showing a process flow of a method for designing the wiring structure of this embodiment and another wiring structure.

Initially, in an input step S7002, data 7001 of a layout after wiring is input. Next, in a step (a wire width detecting step and a wiring density detecting step) S7003, the wire width of each wire in a wiring pattern of the layout data 7001 input in the input step S7002 is detected, or the wiring density of each wiring region in the wiring pattern is detected. Thereafter, in a step (a wire identifying step and a region identifying step) S7004, a large width wire or a region having a high wiring density in which a step is likely to appear during CMP is identified based on the result of detection by the step S7003 using wire width and wiring density conditions 7005 which are determined, depending on the process.

Thereafter, in a step (a wiring pitch detecting step and an air gap-forbidden region forming and removing step) S7006, a wiring pitch portion is detected which is located in a region around the large-width wire or the high-wiring density region identified by the step S7004 and in which an air gap having a high circular cone portion would be formed. Thereafter, in a step (an air gap-forbidden region forming and removing step) S7007, an air gap-formed region is formed or removed, depending on the result of detection by the step S7006.

Thereafter, in an output step S7008, data 7009 of a layout including the air gap-forbidden region determined by the step S7007 is output.

As described above, in the wiring structure designing method and device of this embodiment, a wiring structure is obtained in which an air gap is not formed in a region having a large-width wire or a wiring density or between wires within a predetermined distance therefrom, so that a top portion of an air gap is not cut out, and therefore, a yield can be secured while leaving a region in which an air gap can be formed.

Note that the large wire width, the high wiring density, and the wiring pitch are determined, depending on the process.

Also, in this embodiment, the formation of an air gap-forbidden region has been described. Alternatively, an air gap-forbidden region which has already been provided may be removed, depending on wire width or wiring density conditions which are determined, depending on the process.

### Second Embodiment

Hereinafter, a wiring structure designing device according to a second embodiment of the present invention and a wiring structure obtained by the designing device will be described.

The wiring structure designing method and device of the first embodiment forbid the formation of an air gap in all of large-width wires, high-density wiring regions, and their vicinities, so that a more number of air gaps than necessary are not formed, and therefore, the low-k property may be hindered.

In this embodiment, by calculating the level of a step of wires, it is determined whether or not an air gap will be formed, instead of forbidding the formation of all air gaps that satisfy conditions which are determined, depending on the process.

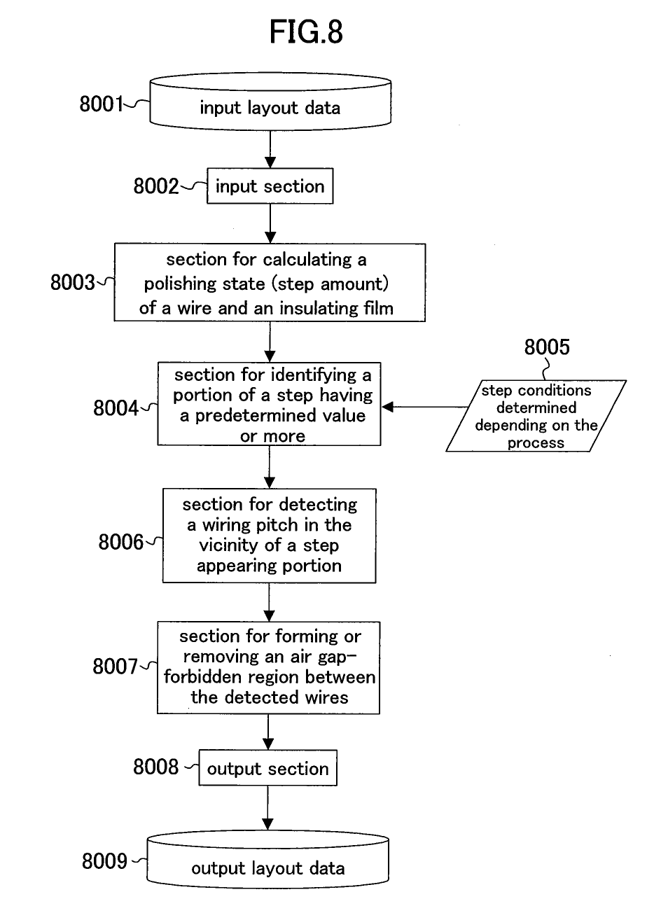

FIG. 8 is a diagram schematically showing a configuration of the wiring structure designing device of the second embodiment of the present invention.

In FIG. 8, the device for designing a wiring structure of a semiconductor integrated circuit device comprises an input section 8002 for inputting data 8001 of a layout after wiring, a section (evenness detecting section) 8003 for detecting the amounts of steps of a wire and an insulating film from a wiring pattern of the input layout data 8001, a section (wire identifying section) 8004 for identifying a step appearing portion (wire) based on the result of detection by the section 8003 using step conditions 8005 which are determined, depending on the process, a section (air gap-forbidden region forming and removing section) 8006 for detecting a wiring pitch between the portion identified by the section 8004 and another wire, a section (air gap-forbidden region forming and removing section) 8007 for forming or removing an air gap-forbidden region, depending on the result of detection by the section 8006, and an output section 8008 for outputting data 8009 of a layout including the air gap-forbidden region determined by the section 8007.

In the first embodiment, a wire having a predetermined width or more or a wiring region having a predetermined density or more is detected. In this embodiment, a step appearing portion having a predetermined step amount or more is detected.

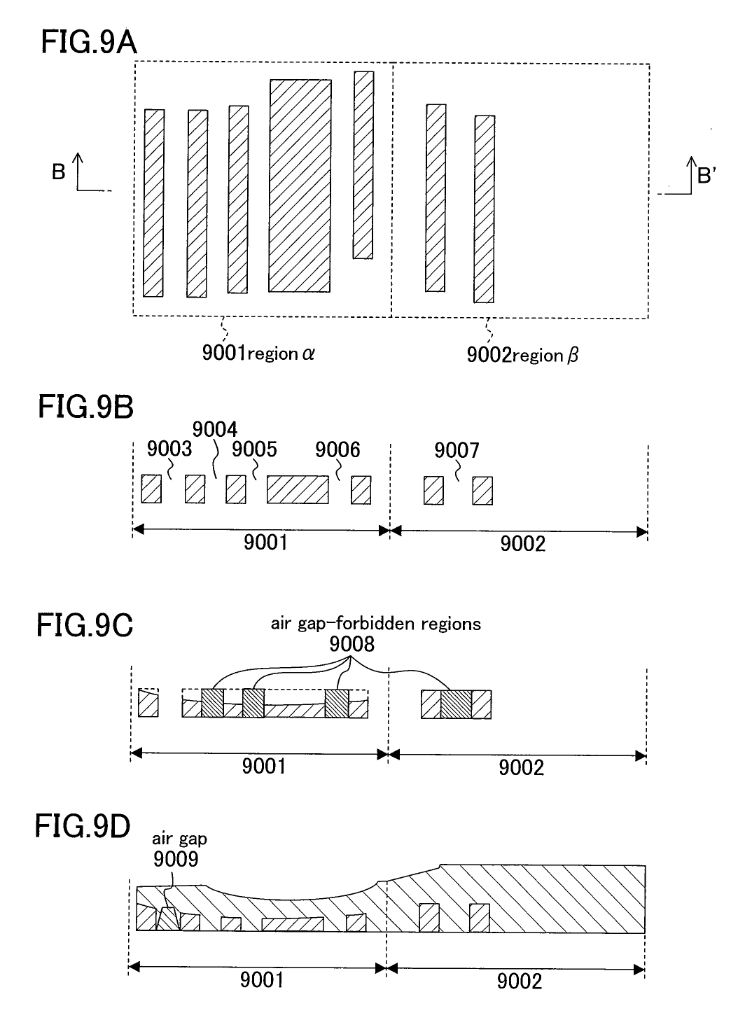

FIGS. 9A to 9D are diagrams showing a wiring structure of one wiring layer of a semiconductor integrated circuit device designed using the wiring structure designing device of this embodiment.

FIG. 9A is a plan view showing a typical wiring pattern in one wiring layer of a multilayer wiring structure. FIG. 9B is a cross-sectional view taken along line B-B′ of FIG. 9A. FIG. 9C is a cross-sectional view taken along line B-B′ of the wiring pattern of FIG. 9A in which air gap-forbidden regions 9008 are formed. FIG. 9D is a cross-sectional view of the wiring pattern of FIG. 9C in which an insulating film is deposited.

FIGS. 9A and 9B are similar to FIGS. 4A and 4B of the first embodiment. In the first embodiment, the formation of an air gap is forbidden in all of the region α 4001 and its vicinity.

In this embodiment, initially, the level of worn-out of the insulating film is calculated to determine whether or not a top portion of an air gap, if it is formed in a region α 9001 and a region therearound, would be cut out. An air gap-forbidden region is formed with respect to only an air gap(s) whose top portion it has been determined that would be cut out.

For example, in FIG. 9B, it is assumed that, of regions 9003, 9004, 9005, 9006, and 9007 in which an air gap can be formed, 9004 to 9007 are regions in which a top portion of an air gap would be cut out if an insulating film is polished. In this case, an air gap-forbidden region 9008 is formed in each of the regions 9004 to 9007, while only an air gap 9009 is left in the region 9003.

Thus, an air gap-forbidden region can be formed only in a portion(s) which would lead to a decrease in yield, thereby making it possible to simultaneously provide both a low-k property and a high yield.

### Third Embodiment

Hereinafter, a wiring structure designing method according to a third embodiment of the present invention and a wiring structure obtained by the designing method will be described.

In this embodiment, an air gap and an air gap-forbidden region are formed between wires under conditions that an air gap-forbidden region is not provided in an entire portion having a predetermined area or more between wires, and an air gap and an air gap-forbidden region are formed in such a portion, so that an air gap can be efficiently formed in portions where an area between wires has a predetermined value or more.

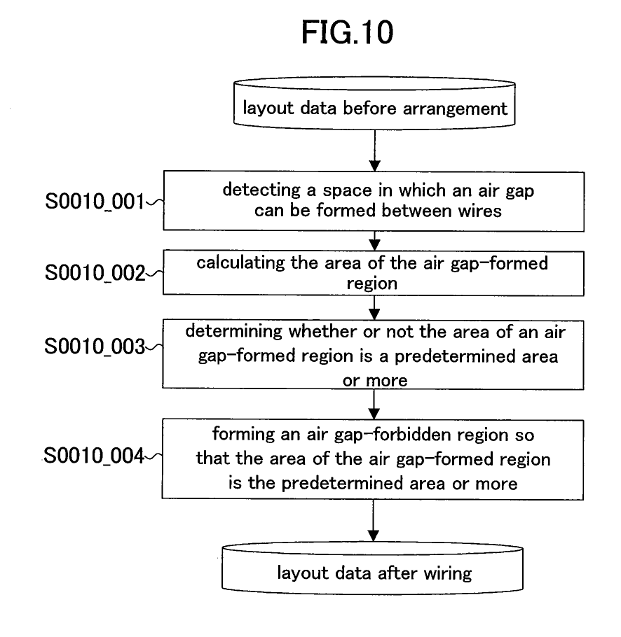

FIG. 10 is a flowchart showing a process flow of the wiring structure designing method of the third embodiment of the present invention.

Hereinafter, the process flow of FIG. 10 will be described.

Initially, in a step (wiring pitch detecting step) S0010_001, a space between wires in which an air gap can be formed (air gap formable region) is detected in a whole chip based on layout data before arrangement.

Next, in a step (area detecting step) S0010_002, the area of an air gap-formed region when an air gap is formed in the air gap formable region detected by the step S0010_001. Thereafter, in a step (area detecting step) S0010_003, it is determined whether or not the region area detected by the step S0010_002 is a predetermined area or more. If the region area is the predetermined area or less, the process flow is ended, or if the region area is the predetermined area or more, the process flow goes to the next step.

In the next step (air gap forming step) S0010_004, an air gap-forbidden region is set so as to divide an air gap so that the air gap-formed region will have the predetermined area (used in the step S0010_003) or less in a target air gap-formed region.

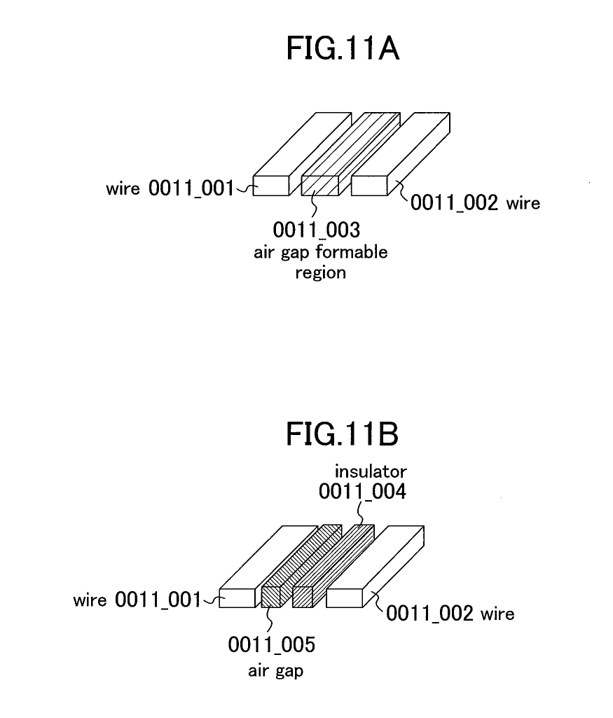

FIGS. 11A and 11B are layout diagrams of a wiring structure of one wiring layer of a semiconductor integrated circuit device designed by the wiring structure designing method of this embodiment.

FIG. 11A is a layout diagram before the wiring structure designing method of this embodiment is performed, where an air gap formable region 0011_003 is provided between a wire 0011_001 and a wire 0011_002. FIG. 11B is a layout diagram after the wiring structure designing method of this embodiment is performed. The air gap formable region 0011_003 of FIG. 11A is divided into an insulator (an air gap-forbidden region, an insulating film) 0011_004 and an air gap 0011_005.

As described above, in the wiring structure of this embodiment and the designing method thereof, an air gap-forbidden region is not formed in an entire air gap formable region having a predetermined area or more between wires, so that an air gap is efficiently formed, as is different from the conventional art in which an air gap-forbidden region is formed in an entire air gap formable region having a predetermined area or more between wires.

### Fourth Embodiment

Hereinafter, a wiring structure according to a fourth embodiment of the present invention will be described.

A portion in which an air gap is formed does not have an insulating film, and therefore, has an insufficient strength as compared to a portion in which an air gap is not formed. This embodiment is characterized by a multilayer wiring structure in which an air gap is formed only either in odd-number wiring layers or even-number wiring layers.

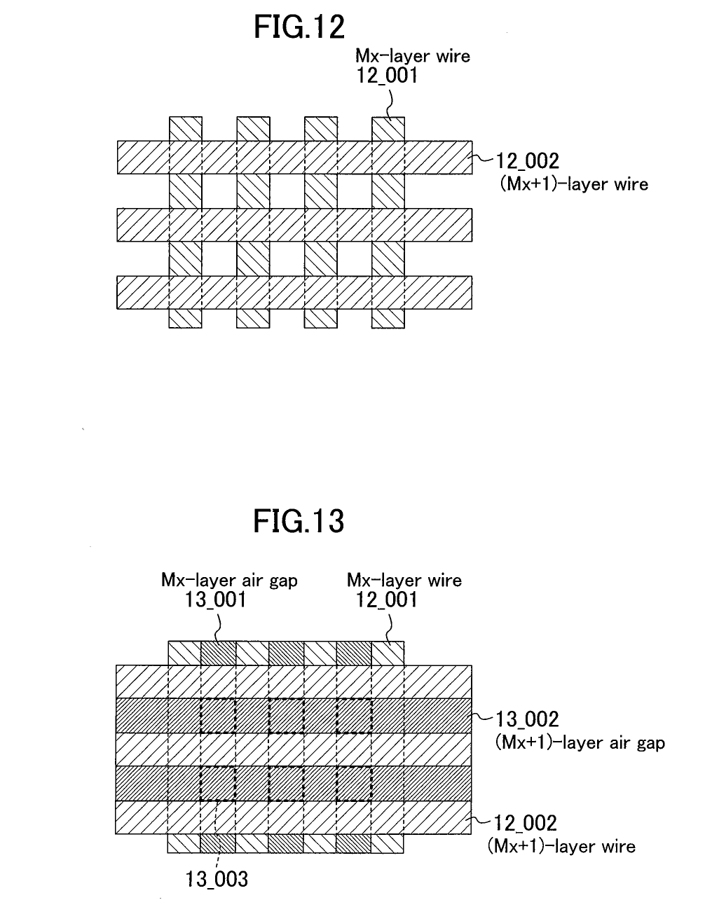

FIG. 12 is a plan view of the wiring structure of a semiconductor integrated circuit device of the fourth embodiment of the present invention.

In FIG. 12, 12_001 indicates an Mx-layer (odd-number layer) wire, and 12_002 indicates an (Mx+1)-layer (even-number layer) wire.

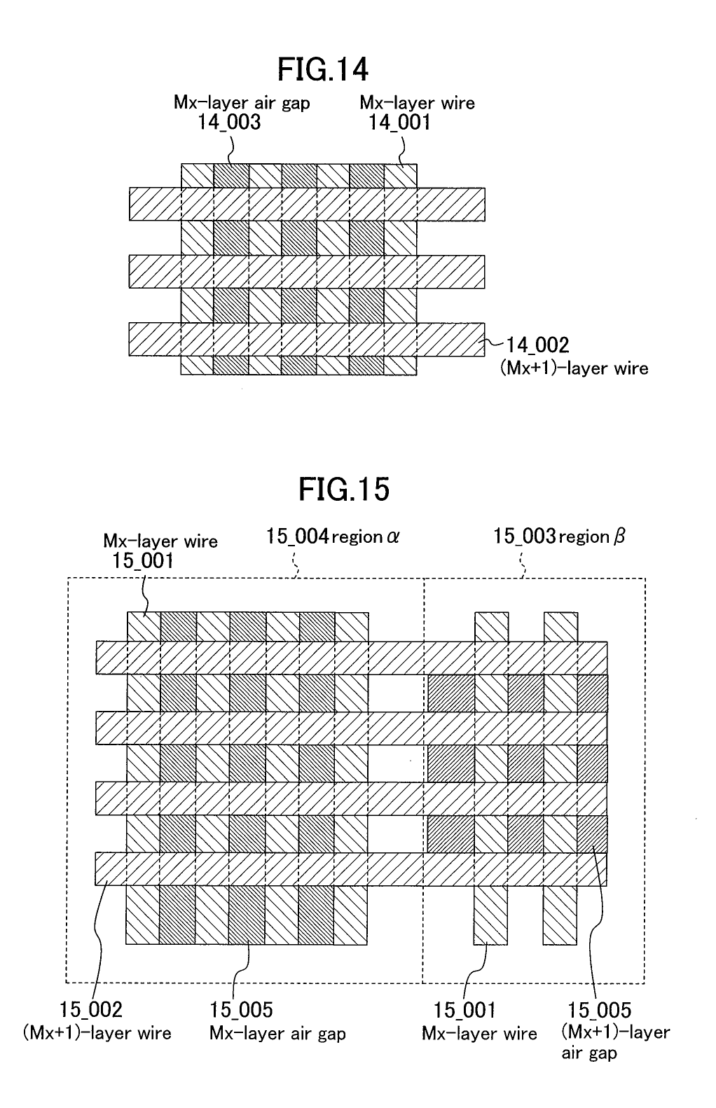

FIG. 13 is a plan view of a conventional multilayer wiring structure of a semiconductor integrated circuit device having an air gap. FIG. 14 is a plan view of a multilayer wiring structure of a semiconductor integrated circuit device having an air gap according to the present invention.

In the conventional wiring structure having an air gap, as shown in FIG. 13, an Mx-layer air gap 13_001 and an (Mx+1)-layer air gap 13_002 are formed with respect to all portions in which it is determined that an air gap can be formed, so as to promote the low-k property. In this case, portions 13_003 where the Mx-layer air gap 13_001 and the (Mx+1)-layer air gap 13_002 overlap each other are formed, so that a plurality of portions having a less strength are present, leading to a decrease in yield.

Therefore, as shown in FIG. 14, in a multilayer wiring structure, an air gap is permitted to be formed in Mx layers (odd-number layers), while an air gap is not permitted to be formed in (Mx+1) layers (even-number layers), so that an air gap is not formed in consecutive layers, thereby making it possible to avoid the insufficiency of strength.

In this case, for example, a timing path for which a low-k property is desired and accurate setup timing is required is formed of an odd-number layer (Mx layer), while a timing path for which an increase in wire delay is desired and accurate hold timing is required is formed of an even-number layer ((Mx+1) layer), so that it is desirable to determine a wiring layer which is used with higher priority, depending on the timing path.

In a process in which air gaps are normally forbidden and a mask is added to air gap forming portions, a mask for forming an air gap may be added to only either odd-number wiring layers or even-number wiring layers, resulting in a reduction in mask cost.

Note that, in this embodiment, odd-number layers (Mx layers) are set as wiring layers in which an air gap can be formed, while even-number layers ((Mx+1) layers) are set as wiring layers in which formation of an air gap is forbidden. Alternatively, odd-number layers (Mx layers) and even-number layers ((Mx+1) layers) may be reversely set.

FIG. 15 is a plan view of another multilayer wiring structure of a semiconductor integrated circuit device having an air gap according to the present invention.

Also, in this embodiment, an air gap can be formed in odd-number layers while an air gap is forbidden to be formed in even-number layers, in a whole chip. Alternatively, as shown in FIG. 15, in a region α 15_004, Mx-layer air gaps 15_005 may be formed in Mx layers while formation of an air gap may be forbidden in (Mx+1) layers, and in a region β 15_003, formation of an air gap may be forbidden in the Mx layers while (Mx+1)-layer air gaps 15_005 may be formed in the (Mx+1) layers. Either setting may be used, depending on the configuration of a timing path and a circuit.

### Fifth Embodiment

Hereinafter, a wiring structure designing method according to a fifth embodiment of the present invention and a wiring structure obtained by the designing method will be described.

In the wiring structure of the fourth embodiment, an air gap is formed only either in odd-number wiring layers or even-number wiring layers, so that the strength can be maintained. However, the low-k property may be limited and the efficiency of wiring may be deteriorated.

In this embodiment, an air gap-forbidden region is formed only in a portion(s) in which air gaps in consecutive layers overlap each other, instead that air gap formation is limited to either odd-number layers or even-number layers.

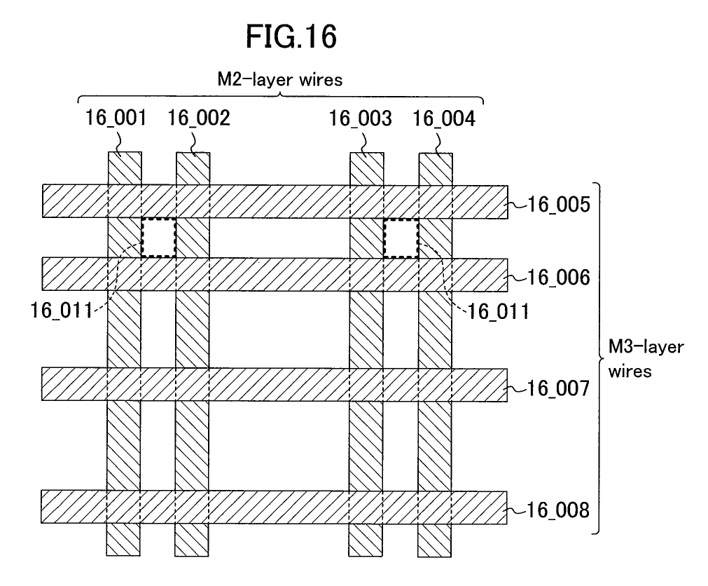

FIG. 16 is a plan view of the wiring structure of a semiconductor integrated circuit device of the fifth embodiment of the present invention.

In FIG. 16, it is assumed that an air gap can be formed between M2-layer wires 16_001 and 16_002, between M2-layer wires 16_003 and 16_004, and between M3-layer wires 16_005 and 16_006, and an air gap is not formed between M3-layer wires 16_007 and 16_008, where the M2-layer wire is formed of a Metal2 layer, and the M3-layer wire is formed of a Metal3 layer.

If air gap formation is limited to odd-number layers as in the fourth embodiment, an air gap is forbidden to be formed between the M2-layer wires 16_001 and 16_002 and between the M2-layer wires 16_003 and 16_004.

In this embodiment, an air gap-forbidden region is provided with respect to a region 16_011 in which an air gap would be otherwise formed in two consecutive layers.

Hereinafter, a specific procedure will be described.

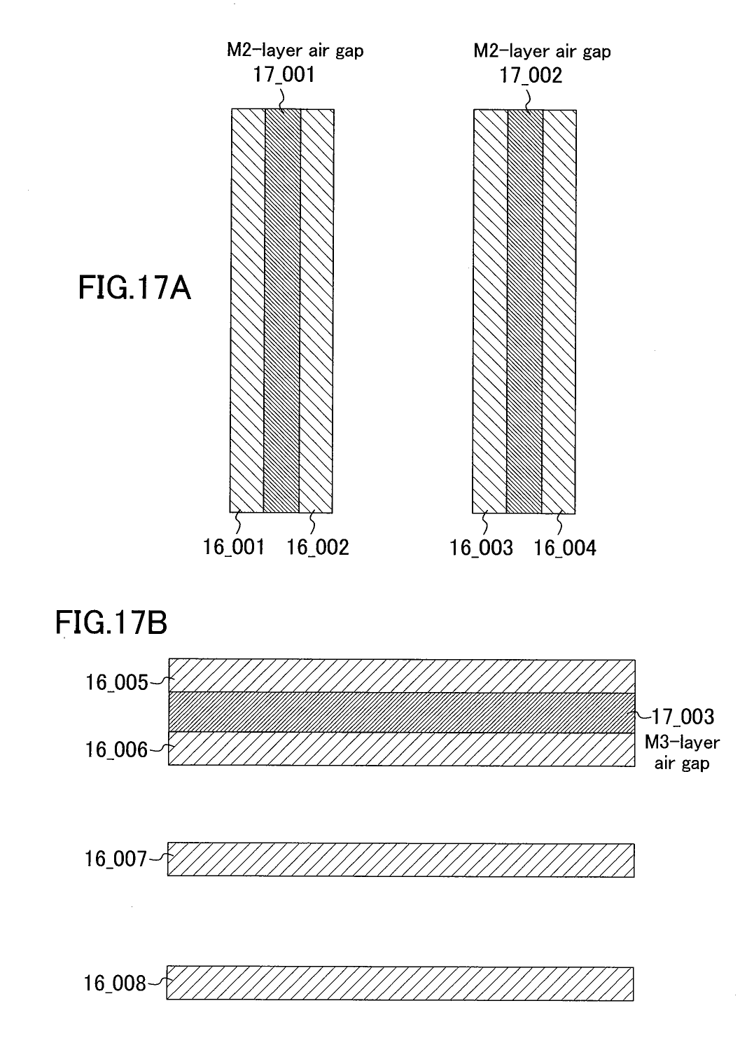

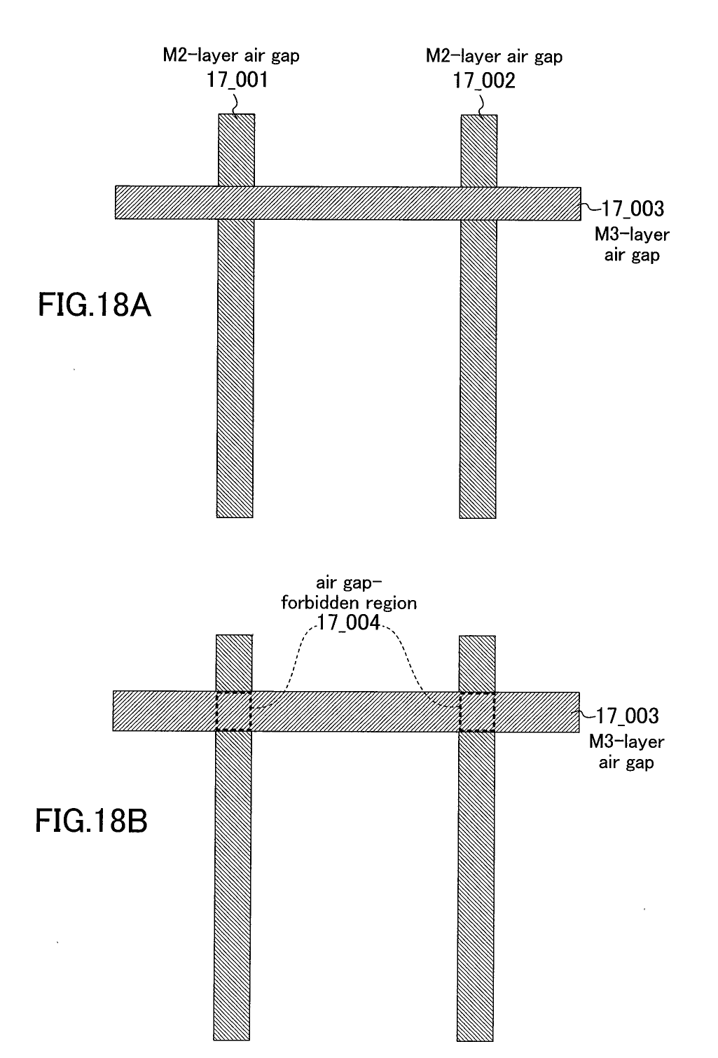

FIGS. 17A and 17B are diagrams showing a process of the wiring structure designing method of this embodiment. FIGS. 18A and 18B are diagrams showing a process of steps following FIGS. 17A and 17B of the wiring structure designing method of this embodiment.

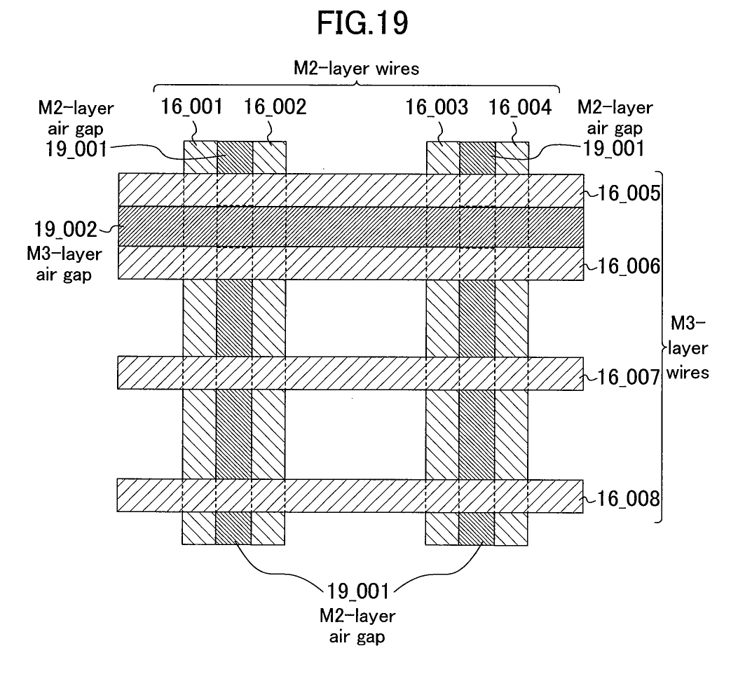

FIG. 19 is a plan view of a wiring structure of a semiconductor integrated circuit device having an air gap according to this embodiment.

Initially, as shown in FIGS. 17A and 17B, an air gap-formed region is extracted from each layer. M2-layer air gaps 17_001 and 17_002 are extracted from the Metal2 layer, and an M3-layer air gap 17_003 is extracted from the Metal3 layer.

Next, as shown in FIGS. 18A and 18B, a portion where extracted air gap-formed regions overlap each other is extracted by a logic operation. Specifically, a logical multiplication (AND) of the M2-layer air gap 17_001, the M2-layer air gap 17_002, and the M3-layer air gap 17_003 is calculated. Thereafter, air gap-forbidden regions 17_004 are formed with respect to portions where the air gap-formed regions overlap each other.

In this case, an air gap-forbidden region can be set at least either in the Metal2 layer or the Metal3 layer. In this embodiment, an air gap-forbidden region is formed in the Metal2 layer.

Thereby, as shown in FIG. 19, consecutive air gaps are not formed between the M2-layer wires 16_001 and 16_002, between the M2-layer wires 16_003 and 16_004, or between the M3-layer wires 16_005 and 16_006. Also, an air gap-forbidden region is not formed in the other regions, so that the low-k property can be maintained.

As described above, by providing the step of determining whether or not consecutive air gaps would be formed, an air gap-forbidden region can be formed only in a portion(s) which would have an insufficient strength, thereby making it possible to simultaneously achieve both the low-k property and prevention of a reduction in yield.

It is noted that the air gap-forbidden region formed in a layer above or below the air gap by the above scheme, for example, 17_004, has the same length as that of the air gap and the same width as that of a closest air gap in the same wiring layer as that of the air gap-forbidden region.

### Sixth Embodiment

Hereinafter, a wiring structure designing method according to a sixth embodiment of the present invention and a wiring structure obtained by the designing method will be described.

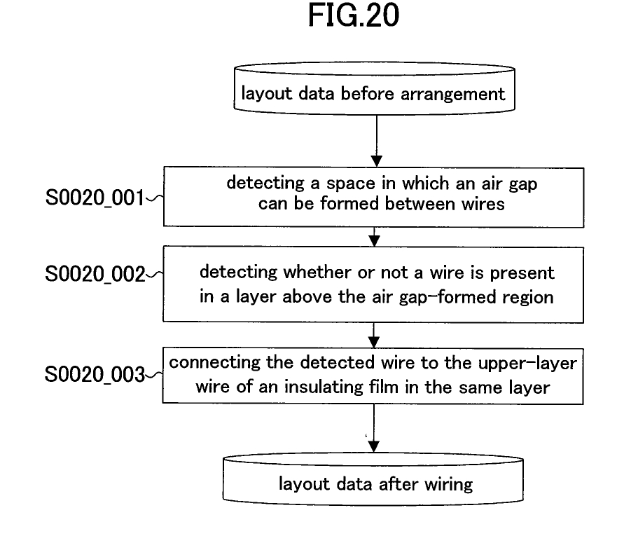

FIG. 20 is a flowchart showing a process flow of the wiring structure designing method of the sixth embodiment of the present invention.

Hereinafter, the process flow of FIG. 20 will be described.

Initially, in a step (wiring pitch detecting step) S0020_001, a space between wires in which an air gap can be formed (air gap formable region) is detected in a whole chip based on input data of a layout before arrangement.

Next, in a step (upper-layer wire detecting step) S0020_002, it is detected whether or not an upper-layer wire is present in an upper-layer region of an air gap-formed region when an air gap is formed in the air gap formable region detected by the step S0020_001. If an upper-layer wire has not been detected in the step S0020_002, the process flow is ended. If an upper-layer wire has been detected in the step S0020_002, the process flow goes to the next step.

In the next step (upper-layer wire connecting step) S0020_003, the upper-layer wire detected by the step S0020_002 is connected to a wire which is provided on an insulating film in the same layer as that of the upper-layer wire and have the same potential as that of the upper-layer wire, or a dummy metal.

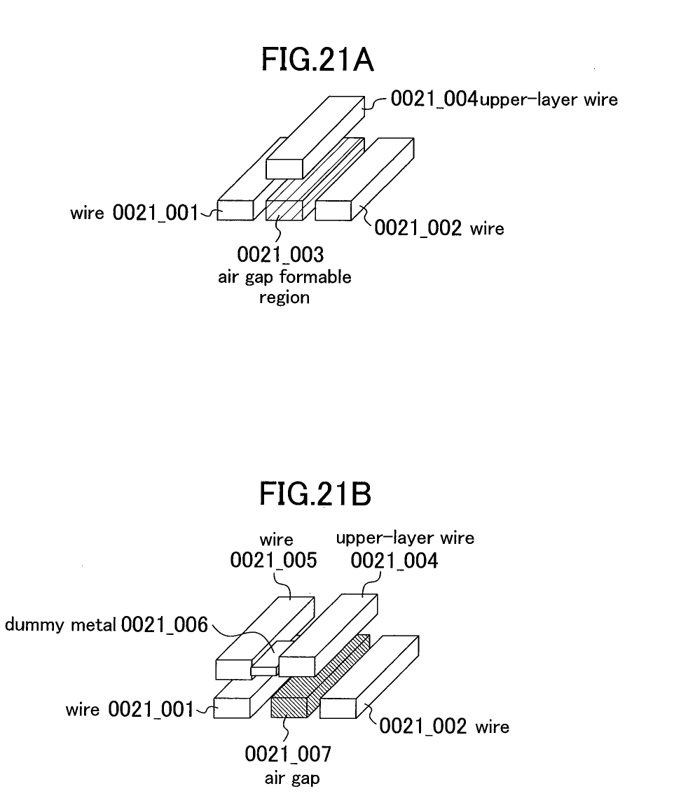

FIGS. 21A and 21B are diagrams showing a layout of a wiring structure of a semiconductor integrated circuit device designed using the wiring structure designing method of this embodiment.

FIG. 21A is a layout diagram before the wiring structure designing method of this embodiment is performed, in which an air gap formable region 0021_003 is provided between a wire 0021_001 and a wire 0021_002, and an upper-layer wire 0021_004 is provided in a layer above the air gap formable region 0021_003.

FIG. 21B is a layout diagram after the wiring structure designing method of this embodiment is performed, in which the upper-layer wire 0021_004 provided above the air gap formable region 0021_003 of FIG. 21A is connected via a dummy metal 0021_006 to a wire 0021_005 which is provided in the same wiring layer as that of the upper-layer wire 0021_004 and has the same potential as that of the upper-layer wire 0021_004. Also, an air gap 0021_007 is formed in the air gap formable region 0021_003.

Thus, in the wiring structure designing method of this embodiment, an upper-layer wire provided in a layer above an air gap is connected to a wire provided in the same wiring layer as that of the upper-layer wire and the like, making it possible to prevent the upper-layer wire from sliding down into the air gap therebelow.

Note that the wire connected via the dummy metal may be either a dummy metal or a wire which has the same potential as that of that wire.

### Seventh Embodiment

Hereinafter, a wiring structure designing method according to a seventh embodiment of the present invention and a wiring structure obtained using the designing method will be described.

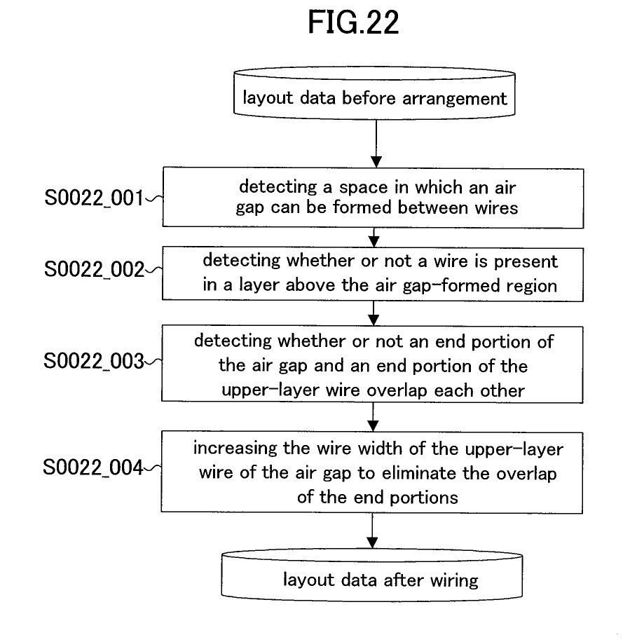

FIG. 22 is a flowchart showing a process flow of the wiring structure designing method of the seventh embodiment of the present invention.

Hereinafter, the process flow of FIG. 22 will be described.

Initially, in a step (wiring pitch detecting step) S0022_001, a space between wires in which an air gap can be formed (an air gap formable region) is detected in a whole chip based on data of a layout before arrangement.

Next, in a step (upper-layer wire detecting step) S0022_002, it is detected whether or not an upper-layer wire is present in an upper-layer region of the air gap-formed region when an air gap is formed in the air gap formable region detected by the step S0022_001. If an upper-layer wire has not been detected in the step S0022_002, the process flow is ended. If an upper-layer wire has been detected in the step S0022_002, the process flow goes to the next step.

In the next step (overlap avoiding step) S0022_003, it is detected whether or not an end portion on the entirety of at least one side of the upper-layer wire detected by the step S0022_002 overlaps an end portion of the air gap-formed region. If overlap has not been detected in the step S0022_003, the process flow is ended. If overlap has been detected, the process flow goes to the next step.

In the next step (overlap avoiding step) S0022_004, in order to prevent the end portion of the entirety of the side of the upper-layer wire detected by the step S0022_003 from overlapping the end portion of the air gap, the wire width of the upper-layer wire is increased so as to avoid the overlap with the end portion of the air gap-formed region.

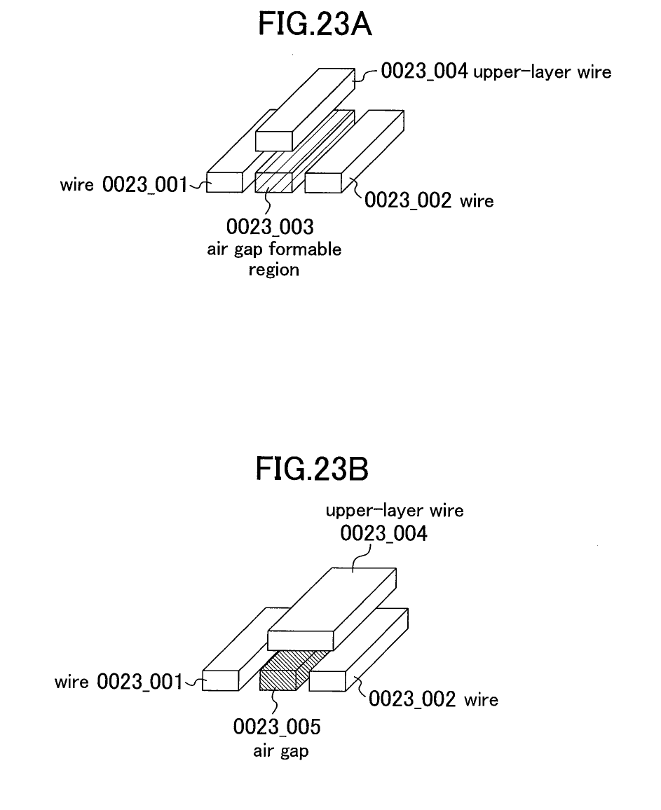

FIGS. 23A and 23B are layout diagrams of the wiring structure of a semiconductor integrated circuit device designed using the wiring structure designing method of this embodiment.

FIG. 23A is a layout diagram before the wiring structure designing method of this embodiment is performed, in which an air gap formable region 0023_003 is provided between a wire 0023_001 and a wire 0023_002, and an upper-layer wire 0023_004 is provided in a layer above the air gap formable region 0023_003.

FIG. 23B is a layout diagram after the wiring structure designing method of this embodiment is performed, in which, in order to prevent an end portion of the air gap formable region 0023_003 and the entirety of one side of the upper-layer wire 0023_004 of FIG. 23A from overlapping each other, the wire width of the upper-layer wire 0023_004 is increased so as to avoid overlap with an air gap 0023_005 formed in the air gap formable region 0023_003.

Thus, in the wiring structure designing method of this embodiment, by increasing the wire width of the upper-layer wire 0023_004 provided in a layer above the air gap 0023_005, the upper-layer wire 0023_004 can be prevented from sliding down into the air gap 0023_005.

Note that another method capable of avoiding overlap of the end portions of the air gap 0023_005 and the upper-layer wire 0023_004 can be used instead of increasing the wire width of the upper-layer wire 0023_004.

### Eighth Embodiment

Hereinafter, a wiring structure designing method according to an eighth embodiment of the present invention and a wiring structure obtained using the designing method will be described.

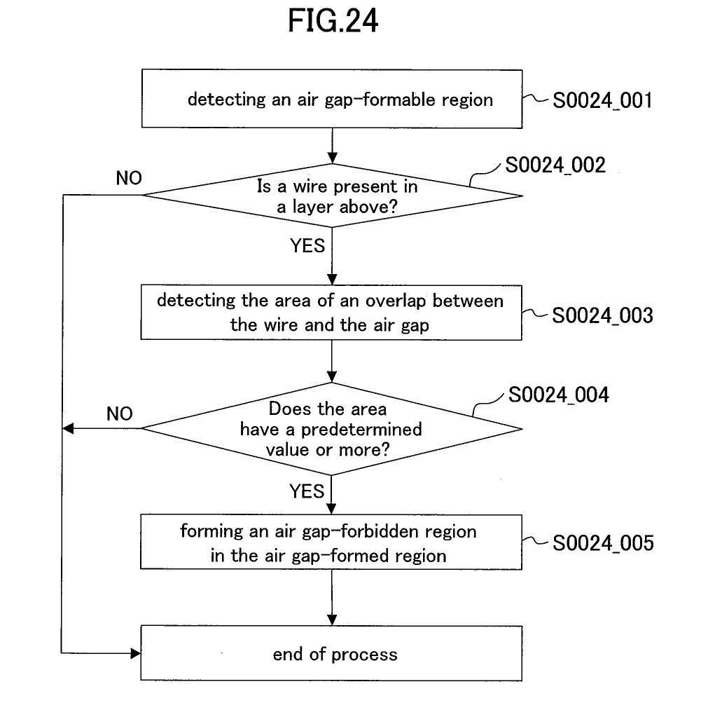

FIG. 24 is a flowchart showing a process flow of a wiring structure designing method according to an eighth embodiment of the present invention.

Hereinafter, the process flow of FIG. 24 will be described.

Initially, in a step (wiring pitch detecting step) S0024_001, a wiring pitch in which an air gap can be formed (an air gap formable region) is detected in a whole chip.

Next, in a step (upper-layer wire detecting step) S0024_002, it is detected whether or not an upper-layer wire is present in an upper-layer region of an air gap-formed region when an air gap is formed in the air gap formable region detected by the step S0024_001. If an upper-layer wire has not been detected in the step S0024_002, the process flow is ended. If an upper-layer wire has been detected, the process flow goes to the next step.

In the next step (overlap area detecting step) S0024_003, an overlap area between the upper-layer wire detected by the step 0024_002 and an air gap-formed region which would overlap the upper-layer wire. Thereafter, in a step (air gap-forbidden region forming step) S0024_004, it is detected whether or not the overlap area detected by the step S0024_003 is a predetermined area or more. If the overlap area is the predetermined area or less, the process flow is ended. If the overlap area is the predetermined area or more, the process flow goes to the next step.

In the next step (air gap-forbidden region forming step) S0024_005, in a target air gap-formed region, an air gap-forbidden region is set so as to divide an air gap so that an area smaller than or equal to the predetermined area used by the step S0024_003 is obtained.

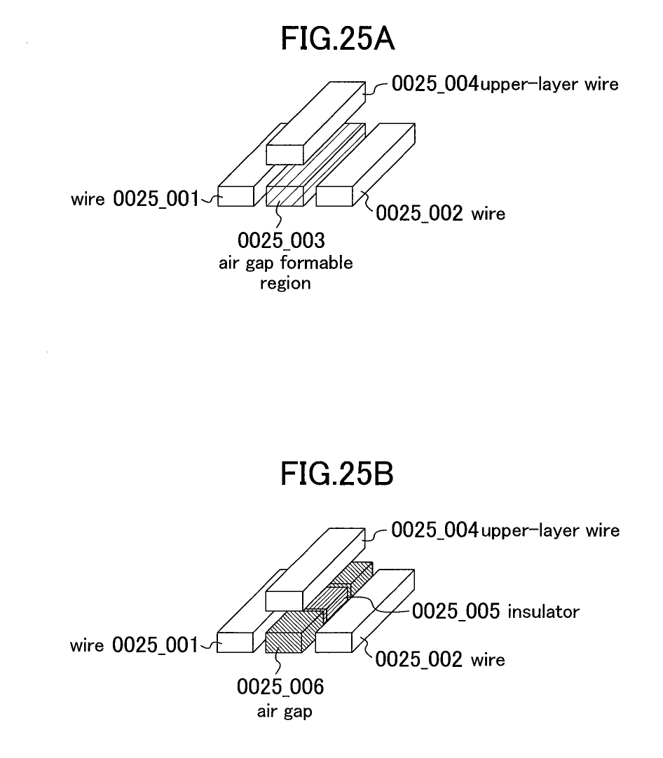

FIGS. 25A and 25B are layout diagrams of the wiring structure of a semiconductor integrated circuit device designed using the wiring structure designing method of this embodiment.

FIG. 25A is a layout diagram before the wiring structure designing method of this embodiment is performed, in which an air gap formable region 0025_003 is provided between a wire 0025_001 and a wire 0025_002, and an upper-layer wire 0025_004 is provided in a layer above the air gap formable region 0025_003.

FIG. 25B is a layout diagram after the wiring structure designing method of this embodiment is performed, in which an insulator 0025_005 is provided in the air gap formable region 0025_003 of FIG. 25A to divide an air gap 0025_006.

Thus, in the wiring structure designing method of this embodiment, by providing the insulator 0025_005 which divides the air gap 0025_006 in the air gap formable region 0025_003, the upper-layer wire 0025_004 is prevented from sliding down into the air gap 0025_006.

### Ninth Embodiment

Hereinafter, a wiring structure designing method according to a ninth embodiment of the present invention and a wiring structure obtained using the designing method will be described.

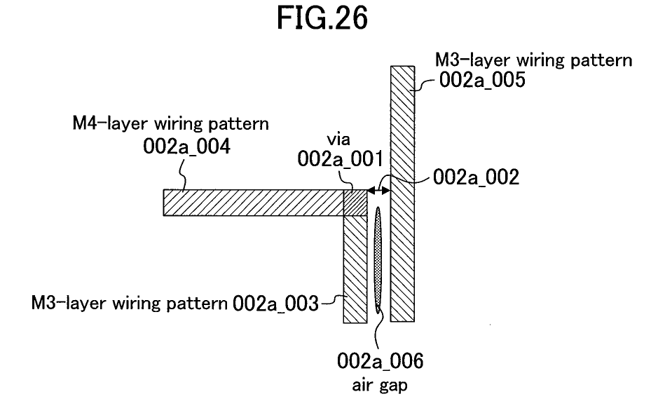

FIG. 26 is a plan view of the wiring structure of a semiconductor integrated circuit device according to the ninth embodiment of the present invention.

In FIG. 26, an M4-layer wiring pattern 002a_004 in a Metal4 layer and an M3-layer wiring pattern 002a_003 in a Metal3 layer are connected to each other via a via 002a_001, and an M3-layer wiring pattern 002a_005 is extended in parallel and beside the M3-layer wiring pattern 002a_003 and the via 002a_001.

In such a wiring structure, an air gap 002a_006 is formed between the M3-layer wiring pattern 002a_003 and the M3-layer wiring pattern 002a_005. In this case, the via 002a_001 is likely to slide down into the air gap 002a_006 due to misalignment occurring during manufacture of the semiconductor integrated circuit device.

In general, in order to prevent missing of a via, the air gap 002a_006 may be caused not to be formed, by providing a predetermined wiring pitch 002a_002 between the M3-layer wiring pattern 002a_003 which is an underlying layer connected to the via and the M3-layer wiring pattern 002a_005 which is provided in the same layer in the vicinity thereof. However, this method for providing the wiring pitch, a space between wires in which the air gap 002a_006 is not formed is required, so that a wire resource is largely wasted. In addition, an air gap having a high circular cone portion is formed, depending on the wiring pitch, so that a hole appears during polishing, resulting in a decrease in yield.

On the other hand, in a method for identifying an air gap-forbidden region, an air gap forbidding film is additionally required, resulting in an increase in cost.

The present invention prevents missing of a via without providing an air gap forbidding film, i.e., without using an excessive wire resource.

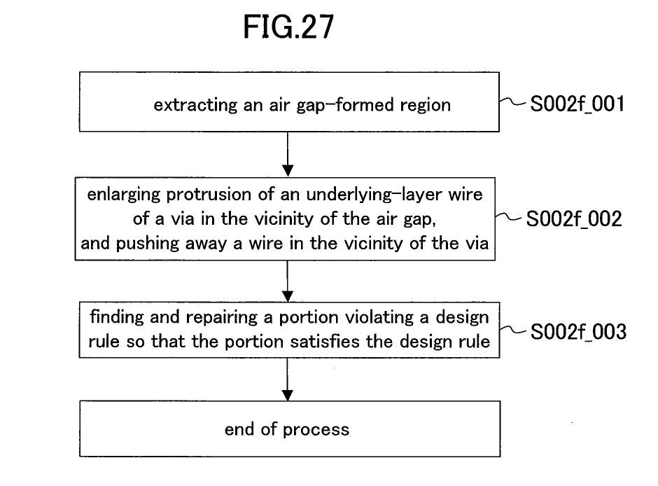

FIG. 27 is a flowchart showing a process flow of the wiring structure designing method of this embodiment, indicating a procedure for preventing missing of a via using protrusion and enlargement of a wire below the via.

Hereinafter, the process flow of FIG. 27 will be described.

Initially, in a step (air gap-formed region extracting step) S002f_001, an air gap-formed region is extracted based on a wiring pattern of data of a layout after wiring.

Next, in a step (an adjacent via identifying step, a wire side detecting step, a wire protrusion amount increasing step, and a surrounding wire moving step) S002f_002, a via adjacent to the air gap-formed region detected in the step S002f_001 is identified, a wire which is connected to the via is detected, and a side of the wire which contacts the air gap-formed region is detected. Thereafter, the side of the wire is enlarged to increase a protrusion amount of the wire connected to the via. Also, when the protrusion amount is increased, wires surrounding that wire are moved as required.

Thereafter, in a step S002f_003, portions which violate a design rule are found and repaired so that layout data including the wire whose protrusion amount has been increased by the step S002f_002 satisfies the design rule.

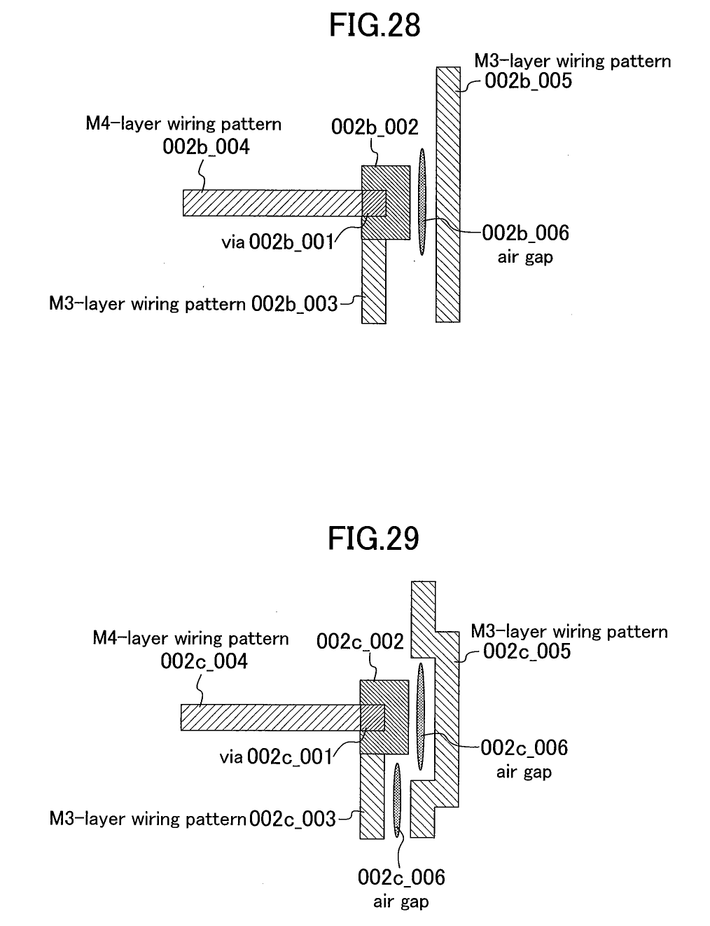

FIG. 28 is a plan view of a wiring structure of a semiconductor integrated circuit device designed using the wiring structure designing method of this embodiment. FIG. 29 is a plan view of another wiring structure of a semiconductor integrated circuit device. These wiring structures are obtained by applying the wiring structure designing method of this embodiment to the wiring structure of FIG. 26. FIG. 28 shows an exemplary wiring structure in which a nearby wire does not need to be pushed away. FIG. 29 shows an exemplary wiring structure in which a nearby wire needs to be pushed away.

Hereinafter, a characteristic wiring structure of this embodiment will be described with reference to FIG. 29.

In the present invention, a protrusion 002c_002 of an M3-layer wiring pattern 002c_003 which is a wire provided in a layer below a via 002c_001 is enlarged toward an M3-layer wiring pattern 002c_005 in a direction in which an air gap 002c_006 is formed, so that the via 002c_001 is prevented from being missing with respect to the air gap 002c_006. Accordingly, the M3-layer wiring pattern 002c_003 has a larger protrusion 002c_002 amount in the direction in which the air gap 002c_006 is present than in the other directions.

If an error occurs in the design rule relating to the M3-layer wiring pattern 002c_005 extended in parallel with the protrusion 002c_002 by enlarging the protrusion 002c_002 of the wire in the layer below the via, the M3-layer wiring pattern 002c_005 is pushed away. The M3-layer wiring pattern 002c_005 of FIG. 29 is obtained by pushing away the M3-layer wiring pattern 002a_005 of FIG. 26.

As described above, in this embodiment, the protrusion 002c_002 of the underlying layer wire 002c_003 connected to the via 002c_001 is enlarged to secure a sufficient protrusion length, thereby making it possible to prevent the via 002c_001 from being missing with respect to the air gap 002c_006, without forming an air gap-forbidden region.

Note that the protrusion 002c_002 of the underlying layer wire 002c_003 of the via 002c_001 may be enlarged before wiring.

Also, the protrusion length of an underlying wire connected to each via provided in a semiconductor integrated circuit device takes a minimum value that prevents penetration between an air gap and the via due to misalignment occurring during manufacture of the semiconductor integrated circuit device, and is determined, depending on the semiconductor manufacturing process.

### Tenth Embodiment

Hereinafter, a wiring structure designing method according to a tenth embodiment of the present invention and a wiring structure obtained using the designing method will be described.

In general, the measures for prevention of missing of a via largely consume a wire resource as described in the ninth embodiment.

The present invention is characterized in that missing of a via is prevented without providing an air gap forbidding film, i.e., without excessively consuming a wire resource.

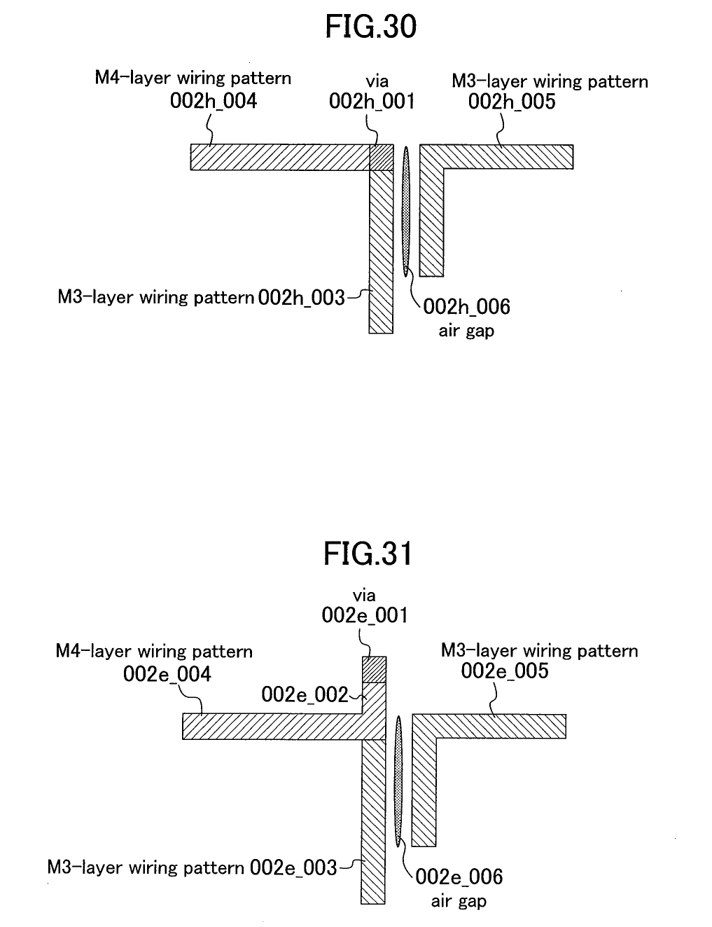

FIG. 30 is a plan view of the wiring structure of a semiconductor integrated circuit device according to the tenth embodiment of the present invention. FIG. 31 is a plan view of another wiring structure of a semiconductor integrated circuit device of this embodiment.

In FIG. 30, an M4-layer wiring pattern 002h_004 in a Metal4 layer and an M3-layer wiring pattern 002h_003 in a Metal3 layer are connected to each other via a via 002h_001, and an M3-layer wiring pattern 002h_005 in the Metal3 layer is extended beside and in parallel with the M3-layer wiring pattern 002h_003 and the via 002h_001.

In the case of such a wiring structure, an air gap 002h_006 is formed between the M3-layer wiring pattern 002h_003 and the M3-layer wiring pattern 002h_005. In the wire arrangement of FIG. 30, the via 002h_001 is typically provided at an intersection of the M4-layer wiring pattern 002h_004 in the Metal4 layer and the M3-layer wiring pattern 002h_003 in the Metal3 layer in view of efficient usage of a wire resource.

In the present invention, by moving the via 002h_001 of FIG. 30 to the position of a via 002e_001 of FIG. 31, a via is prevented from being missing with respect to the air gap 002h_006 (002e_006 in FIG. 31).

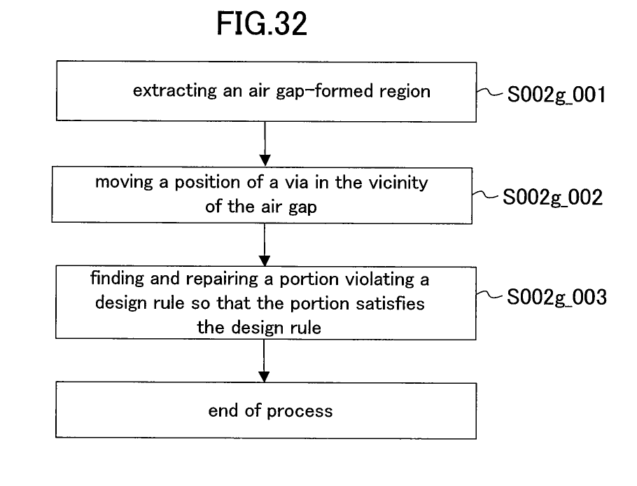

FIG. 32 is a flowchart showing a process flow of the wiring structure designing method of this embodiment.

Hereinafter, the process flow of FIG. 32 will be described.

Initially, in a step (air gap-formed region extracting step) S002g_001, an air gap-formed region is extracted based on a wiring pattern of data of a layout after wiring.

Next, in a step (an adjacent via identifying step and a via position changing step) S002g_002, a via adjacent to the air gap-formed region detected by the step S002g_001 is identified, and a position of the via is changed. Movement of the via is performed after determination of wiring, while recognizing the presence around the via of the underlying wire 002h_003 connected to the via, and the wire 002h_005 extended in parallel with the wire 002h_003.

Thereafter, in a step S002g_003, portions which violate a design rule are found and repaired so that layout data including the via whose position has been changed by the step 002g_002 satisfies the design rule.

Thus, in this embodiment, by changing the positions of an air gap and a via adjacent thereto, a sufficient distance between the via and the air gap is secured, thereby making it possible to prevent missing of the via with respect to the air gap, without forming an air gap-forbidden region.

Note that the movement of each via provided in a semiconductor integrated circuit device is performed so as to secure a minimum value of an air gap-forbidden region that prevents penetration between an air gap and a via due to misalignment occurring during manufacture of the semiconductor integrated circuit device, and the amount of the movement is determined, depending on the semiconductor manufacturing process.

### Eleventh Embodiment

Hereinafter, a wiring structure designing method according to an eleventh embodiment of the present invention will be described.

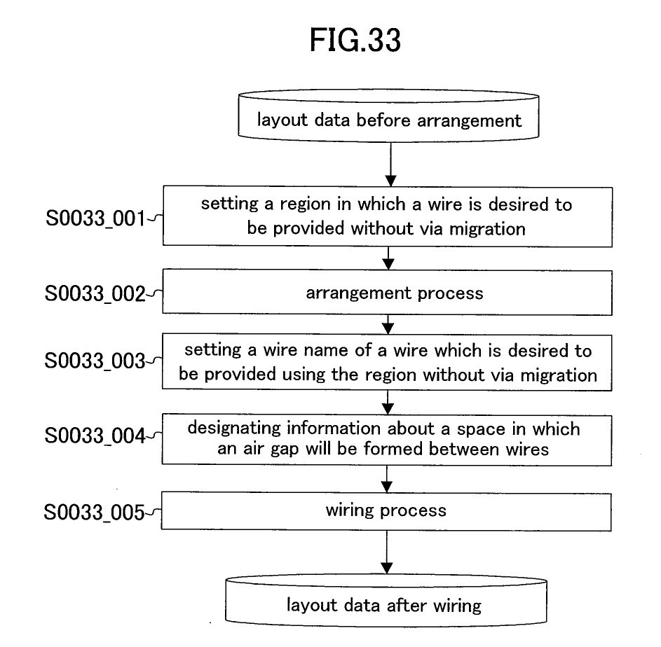

FIG. 33 is a flowchart showing a process flow of the wiring structure designing method of the eleventh embodiment of the present invention.

Initially, in a step (wire forming region designating step) S0033_001, a region in which wiring is desired without a via is set, and in a step S0033_002, a typical arrangement process is performed.

Next, in a step (wire name setting step) S0033_003, the name of a wire desired to be provided in a region in which via migration is not performed is set. In a step (air gap forming pitch designating step) S0033_004, information about a space between wires in which an air gap will be formed is designated.

Thereafter, in a step (wiring pattern forming step) S0033_005, a wiring process is performed in view of the region designated by the step S0033_001 and the wire name designated by the step S0033_003. Specifically, a wiring pattern of the wire set by the step S0033_003 is formed at a wiring pitch smaller than or equal to that which is designated by the step S0033_004, in the region designated by the step S0033_001.

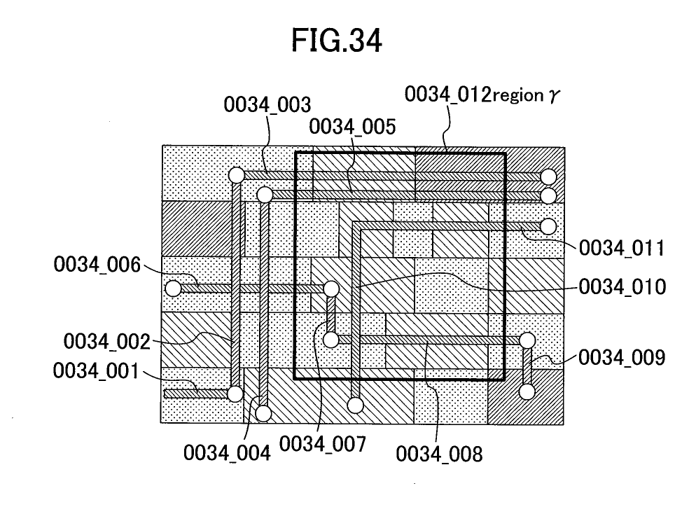

FIG. 34 is a plan view of a wiring structure of a semiconductor integrated circuit device designed using the wiring structure designing method of this embodiment.

In FIG. 34, wires 0034_001 to 0034_0011 are provided. Also, open circles indicate vias connecting wires.

It is here assumed that a region γ 0034_012 is a region set in the step S0033_001 in which wiring is provided without a via, and a wire including the wire 0034_001 to 0034_003, a wire including the wires 0034_004 and 0034_005, and a wire including the wires 0034_010 and 0034_011 are designated as the names of wires designated in the step 0033_003 which are desired without via migration.

In this case, as shown in FIG. 34, a via is not provided in the designated wire present in the designated region γ 0034_012.

Although a via is provided in a wire including the other wires 0034_006 to 0034_009, the via is at a distance from the designated wire. Therefore, the formation of the via does not have an influence on the presence or absence of an air gap.

Here, if a wiring pattern which is adjacent to the designated wiring pattern and is not designated, that wiring pattern is formed without a via.

Thus, in this embodiment, by providing a designated wire in a designated region without using a via, an air gap can be certainly provided, leading to a reduction in capacitance of the wire and a reduction in crosstalk noise. By using this effect, it is possible to provide a wire extending in parallel with a bus wire, which is conventionally difficult to provide.

Note that, in this embodiment, in the step (wire forming region designating step) S0033_001 prior to the step S0033_002 in which a typical arrangement process is performed, a region is set in which a wire is desired to be provided without a via. Alternatively, in the step (wire name setting step) S0033_003, a region may be set after setting the name of a desired wire using a region in which via migration is not performed.

Thus, in the present invention, a wiring pattern can be formed in which a reduction in yield of a wire or a via due to an air gap after the automatic wiring step and the wiring process can be suppressed, and the wiring pattern can be formed in a short period of time. Therefore, particularly, the present invention is useful as a wiring structure of a semiconductor integrated circuit device, a method and device for designing the same, and the like.

What is claimed is:

1. A wiring structure of a wiring layer having an air gap of a semiconductor integrated circuit device, wherein
an air gap is provided only in a wiring region or wiring regions in which a wiring pitch between a large-width wire and another wire has a predetermined value or less.

2. A wiring structure of a wiring layer having an air gap of a semiconductor integrated circuit device, wherein
an air gap is provided only in a wiring region or wiring regions in which a wiring density has a predetermined value or less.

3. A wiring structure of a wiring layer having an air gap of a semiconductor integrated circuit device, wherein
an air gap and an insulating film are provided between wires in the wiring layer.

4. A wiring structure of a semiconductor integrated circuit device having a multilayer wiring structure having an air gap, wherein
an air gap is provided only either in an odd-number layer or layers or an even-number layer or layers in a multilayer wiring layer.

5. A wiring structure of a semiconductor integrated circuit device having a multilayer wiring structure having an air gap, wherein
an air gap is provided only in an odd-number layer or layers in a region of a portion of a multilayer wiring layer, and
an air gap is provided only in an even-number layer or layers in the other region of the multilayer wiring layer.

6. A wiring structure of a semiconductor integrated circuit device having a multilayer wiring structure having an air gap, wherein
an insulating film region formed in a layer above or below the air gap has the same length as that of the air gap, and the same width as that of a closest air gap in the same wiring layer as that of the insulating film region.

7. A wiring structure of a semiconductor integrated circuit device having a multilayer wiring structure having an air gap, wherein
an upper-layer wire present in a layer above the air gap is connected to a wire on an insulating film in the same wiring layer as that of the upper-layer wire at at least one point.

8. A wiring structure of a semiconductor integrated circuit having a multilayer wiring structure having an air gap, wherein
an entirety of at least one side of an upper-layer wire present in a layer above the air gap does not overlap an end portion of the underlying air gap.

9. A wiring structure of a semiconductor integrated circuit having a multilayer wiring structure having an air gap, wherein
at least one insulator is provided in an air gap-formed region of a reference layer and at an overlapping portion between the air gap-formed region of the reference layer and an upper-layer wire present in a layer above the reference layer.

10. A wiring structure of a wiring layer having an air gap of a semiconductor integrated circuit device, wherein
a wire connected to a via adjacent to the air gap has a larger protrusion amount in a direction in which the air gap is present than in the other directions.
